(19) United States
(12) Patent Application Publication
(10) Pub. No.: US 2019/0094306 A1
(43) Pub. Date: Mar. 28, 2019

(54) BATTERY'S RESIDUAL ENERGY MEASUREMENT CIRCUIT AND SENSOR NODE

(71) Applicant: FUJITSU LIMITED, Kawasaki-shi (JP)

(72) Inventor: Kenichi Kawasaki, Kawasaki (JP)

(73) Assignee: FUJITSU LIMITED, Kawasaki-shi (JP)

(21) Appl. No.: 16/133,781

(22) Filed: Sep. 18, 2018

(30) Foreign Application Priority Data
Sep. 25, 2017 (JP) 2017-184029
Feb. 23, 2018 (JP) 2018-031224

(51) Int. Cl. G01R 31/36

(52) U.S. Cl. CPC G01R 31/3617

(57) ABSTRACT

A battery's residual energy measurement circuit includes integrated amount measurement circuitry that measures quantity of an integrated amount of current flowing in a battery, time number measurement circuitry that measures number of times by which a sensing operation that changes the current flowing, time measurement circuitry that measures time, and residual energy calculation circuitry that calculates residual energy of the battery using the integrated amount measured within a measurement period by the integrated amount measurement circuitry, the number of times measured within the measurement period by the time number measurement circuitry and the measurement period measured by the time measurement circuitry.

### CROSS-REFERENCE TO RELATED APPLICATION

This application is based upon and claims the benefit of priority of the prior Japanese Patent Application No. 2018-31224, filed on Feb. 23, 2018, and Japanese Patent Application No. 2017-184029, filed on Sep. 25, 2017, the entire contents of which are incorporated herein by reference.

### FIELD

The embodiments discussed herein are related to a battery's residual energy measurement circuit and a sensor node.

### BACKGROUND

There is a technology which calculates the residual energy of a battery by integrating current outputted from the battery.

Since the current consumption of integrated amount measurement circuitry (for example, a Coulomb counter) that measures the integrated amount of current flowing through a battery is comparatively high, the energy consumption used for measurement of the integrated amount is sometimes suppressed by not usually keeping the integrated amount measurement circuitry operative but rendering the integrated amount measurement circuitry operative intermittently. For example, the integrated amount measurement circuitry is operated only within a certain time zone, and average current flowing within the time zone is calculated based on the integrated amounted measured within the time zone. Then, the overall current integrated amount is predicted assuming that the average current continues to flow also within a period within which the integrated amount measurement circuitry stops.

However, if the current actually flowing through the battery within the period within which the integrated amount measurement circuitry stops fluctuates significantly with respect to the average current, since the error of the predicted overall current integrated amount becomes great, there is the possibility that the calculation accuracy of the battery's residual energy may degrade.

The following is a reference document. [Document 1]Japanese Laid-open Patent Publication No. 2009-183067.

### SUMMARY

According to an aspect of the embodiment, a battery's residual energy measurement circuit includes integrated amount measurement circuitry that measures quantity of an integrated amount of current flowing in a battery, time number measurement circuitry that measures number of times by which a sensing operation that changes the current flowing, time measurement circuitry that measures time, and residual energy calculation circuitry that calculates residual energy of the battery using the integrated amount measured within a measurement period by the integrated amount measurement circuitry, the number of times measured within the measurement period by the time number measurement circuitry and the measurement period measured by the time measurement circuitry.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a view depicting an example of a configuration of an information collection system;

FIG. 2 is a view depicting an example of a configuration of a sensor node in a comparative form;

FIG. 3 is a view depicting an example of a configuration of a Coulomb counter;

FIG. 4 is a view depicting an example of a current waveform;

FIG. 5 is a view depicting an example of operation of a battery's residual energy measurement circuit in a comparative form;

FIG. 6 is a view depicting an example of a configuration of a sensor node according to a first embodiment;

FIG. 7 is a view depicting an example of a functional configuration of a controller;

FIG. 8 is a view depicting an example a relation between a current waveform and a current change detection signal;

FIG. 9 is a view depicting an example of a relation between C_{A} and I_{B};

FIG. 10 is a view depicting a particular example of a calculation algorithm of battery's residual energy;

FIG. 11 is a flow chart depicting an example of operation for calculating and saving C_{A} and I_{B};

FIG. 12 is a flow chart depicting a first operation example of a battery's residual energy measurement circuit;

FIG. 13 is a time chart depicting the first operation example of the battery's residual energy measurement circuit;

FIG. 14 is a flow chart depicting a second operation example of the battery's residual energy measurement circuit;

FIG. 15 is a time chart depicting the second operation example of the battery's residual energy measurement circuit;

FIG. 16 is a view depicting an example of a configuration of a sensor node according to a second embodiment;

FIG. 17 is a view depicting a first configuration example of current change detection circuitry;

FIG. 18 is a view depicting operation waveforms in the first configuration example of the current change detection circuitry;

FIG. 19 is a view depicting a second configuration example of the current change detection circuitry;

FIG. 20 is a view depicting operation waveforms in the second configuration example of the current change detection circuitry;

FIG. 21 is a view depicting an example of a configuration of a sensor node according to a third embodiment;

FIG. 22 is a view depicting an example of an operation waveform of a sensor node;

FIG. 23 is a view depicting a second particular example of a relation between a current waveform and a current change detection signal;

FIG. 24 is a view depicting a second particular example of the calculation algorithm of the battery's residual energy;

FIG. 25 is a flow chart depicting an example of operation for calculating and saving C_{A}, C_{B}, C_{C} and I_{B};

FIG. 26 is a view depicting an example of decision as t_{A};

FIG. 27 is a time chart depicting a third operation example of the battery's residual energy measurement circuit;

FIG. 28 is a time chart depicting a fourth operation example of the battery's residual energy measurement circuit;

FIG. 29 is a flow chart depicting the fourth operation example of the battery's residual energy measurement circuit;

FIG. 30 is a view depicting a third particular example of a relation between a current waveform and a current change detection signal;

FIG. 31 is a view depicting a third particular example of the calculation algorithm of the battery's residual energy;

FIG. 32 is a flow chart depicting an example of operation for calculating and saving I_{A} and I_{B}; and

FIG. 33 is a time chart depicting a fifth operation example of the battery's residual energy measurement circuit.

### DESCRIPTION OF EMBODIMENTS

In the following, embodiments of the present disclosure are described with reference to the drawings.

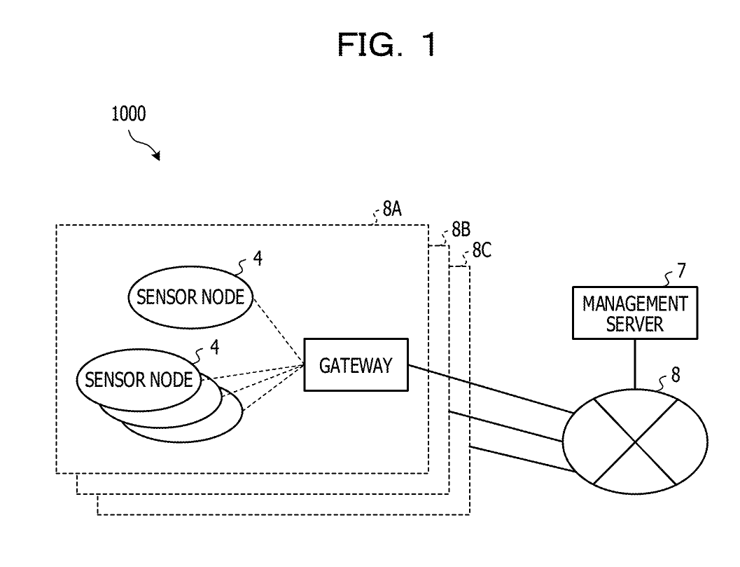

FIG. 1 is a view depicting an example of a configuration of an information collection system according to an embodiment. The information collection system 1000 depicted in FIG. 1 includes a plurality of sensor nodes 4, at least one gateway 5 and at least one management server 7.

By disposing the plurality of sensor nodes 4 in a distributed manner, it is possible to collect observation data (for example, environment data such as the temperature) detected by the sensor nodes 4 in a certain area. At a location at which it is difficult to secure external energy supply, the sensor nodes 4 are driven by electric energy supplied from batteries carried on the individual sensor nodes 4. In such battery-driven sensor nodes 4 as just described, it is important to measure the battery's residual energy with a high degree of accuracy in order to find when to charge or replace the battery on the operation management side.

For example, in a sewer flooding detection system, since the sensor node 4 for sensing the water level of the sewer is disposed just below each manhole, it sometimes is very difficult to lay an energy supply line. Therefore, the sensor nodes 4 are battery-emerged in operation. Further, since the battery replacement operation may require a high cost, it is desirable to extend the battery life span as long as possible. Therefore, in a time zone in which data acquisition is not required, such intermittent operation control that the sensing operation is stopped to suppress unnecessary energy consumption and is executed only in a time zone in which the sensing operation may be required.

Furthermore, in an environment sensing system that collects environment data such as data of the water level, the operation continuity is very significant. If the residual battery energy of the sensor node 4 is used up imperceptibly and a state in which data acquisition is difficult continues, this gives rise to significant decrease in reliability of the entire system. Therefore, in the case where the sensor nodes 4 are of the primary cell driven type, it is significant to find the battery replacement time, and in the case where the sensor nodes 4 are of the secondary battery-driven type like a lithium ion battery, it is significant to find the charging time, with a high degree of accuracy. For example, it is significant to measure the battery's residual energy with a high degree of accuracy.

The management server 7 is an example of a processing apparatus that processes information collected from the plurality of sensor nodes 4. The management server 7 collects the battery's residual energy measured by the sensor nodes 4 from the sensor nodes 4 through the gateway 5 and a network 6 and manages the battery's residual energy of the sensor nodes 4 using the battery's residual energy collected from the sensor nodes 4. Consequently, even if the sensor nodes 4 are distributed over a wide range, the management server 7 may perform remote management such as to monitor the temporal change of the battery's residual energy of the sensor nodes 4. The management server 7 is, for example, a cloud server installed at a place remote from the sensor nodes 4.

As a particular example of observation data to be detected by the sensor nodes 4, temperature, humidity, precipitation, water level, voltage, electric current, electric energy, amount of energy, pressure, communication amount, luminosity, illuminance, acceleration, sound, distortion and so forth may be listed. The observation data is not limited to them.

It is to be noted that the management server 7 may collect observation data detected by the sensor node 4 and residual energy data of the batteries incorporated in the sensor nodes 4 directly from the sensor nodes 4 without the intervention of the gateway 5. Further, the gateway 5 may function as a processing apparatus that processes information collected from the plurality of sensor nodes 4. For example, the gateway 5 may manage the residual energy of the batteries of the sensor nodes 4.

The management server 7 changes the frequency of collection of information from the sensor nodes 4 in response to the residual energy data individually collected from the sensor nodes 4 (for example, the frequency of transmission of the information individually by the sensor nodes 4). Each sensor node 4 uses the energy of the battery incorporated therein for transmission of information. Accordingly, the management server 7 may remotely adjust the battery's residual energy of each of the sensor nodes 4 by changing the frequency of collection of information from the sensor node 4. The management server 7 transmits a data transmission request signal for requesting the sensor nodes 4 for transmission of data such as observation data or residual energy data and may change the frequency of collection of information from each of the sensor nodes by changing the frequency of transmission of the data transmission request signal.

For example, the management server 7 changes the frequency of transmission of information from the sensor nodes 4 for each region such that the battery's residual energies of the sensor nodes 4 may agree with each other in a same region. Consequently, since, for example, the exhaustion timings of the battery's residual energy of the sensor nodes 4 agree with each other in a same region, charging or replacement of the sensor nodes 4 may be performed all at once for each region and the operation management cost decreases. FIG. 1 depicts a form in which a plurality of sensor nodes 4 and a gateway 5 are disposed in each of regions 8A, 8B and 8C.

For example, the management server 7 decreases the frequency of collection of observation data from the sensor nodes 4, whose battery's residual energy data is lower than a reference value in the same region, from the frequency of collection of observation data from the sensor nodes 4 whose battery's residual energy data is higher than the reference value. Alternatively, the management server 7 increases the frequency of collection of observation data from the sensor nodes 4, whose battery's residual energy data is higher than a reference value in the same region, from the frequency of collection of observation data from the sensor nodes 4 whose battery's residual energy data is lower than the reference value.

The management server 7 transmits a data transmission request signal to the gateway 5 in each region through the network 6. The gateway 5 in each region acquires information from the sensor nodes 4 in a region same as the region of itself and uploads the acquired information to the management server 7 through the network 6.

It is to be noted that, although transmission of information between each sensor node 4 and the gateway 5 is performed by short-range wireless communication, the transmission may be performed by wired communication. Further, although transmission of information between each gateway 5 and the network 6 is performed by wired communication, the transmission may be performed by wireless communication. Further, each gateway 5 that manages a respective sensor network may have part of the management function of the management server 7 to form the information collection system 1000 as a distributed management system.

Now, a configuration of the sensor node is described. First, a configuration of a sensor node according to a comparative form is described for the comparison with the sensor node in the present embodiment.

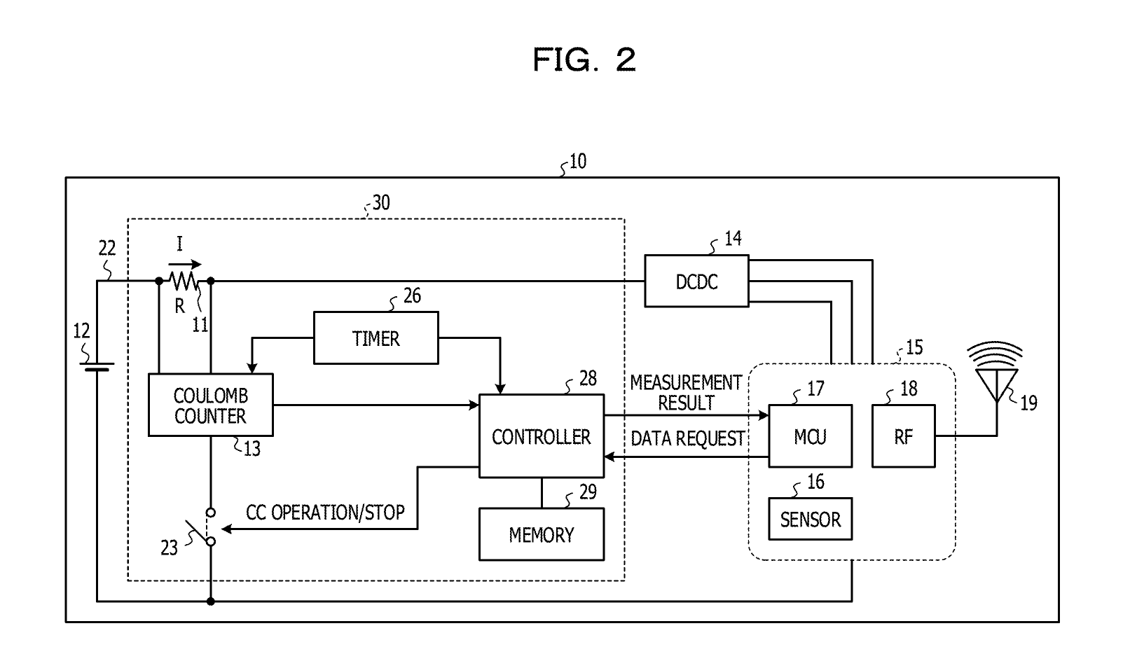

FIG. 2 is a view depicting an example of a configuration of the sensor node in one comparative form. The sensor node 10 depicted in FIG. 2 is an apparatus that uses a battery 12 as an energy supply.

The sensor node 10 is a sensor device including a battery 12, a direct current-direct current (DCDC) converter 14, a battery's residual energy measurement circuit 30, sensor processing circuitry 15 and an antenna 19.

The battery 12 may be a primary cell or may be a rechargeable secondary battery. As a particular example of the primary cell, a dry cell is listed. As a particular example of the secondary battery, a lithium ion battery, a lithium polymer battery and so forth are listed.

The DCDC converter 14 performs step-up or step-down conversion of DC energy of the battery 12 and supplies the stepped up or stepped down DC energy to the sensor processing circuitry 15 and the battery's residual energy measurement circuit 30. The DCDC converter 14 may supply, for example, the stepped down DC energy to part of circuits in the sensor processing circuitry 15 and circuits in the battery's residual energy measurement circuit 30 and supply the stepped up DC energy to the residual circuits. For example, in the case where, while the battery 12 is of 3 Volt, micro controller circuitry (MCU) 17 uses 2.5 Volt as an operating voltage and a sensor 16 uses 5 Volt as an operating voltage, DC energy obtained by step down conversion is supplied to the MCU 17 and DC energy obtained by step up conversion is supplied to the sensor 16. For example, in the case where the MCU 17, the sensor 16 and radio filter (RF) circuitry 18 operate with voltages different from one another, the DCDC converter 14 includes three conversion outputting circuitry that output voltages different from one another with respect to one inputting circuitry to which the battery voltage of the battery 12 is inputted.

The battery's residual energy measurement circuit 30 measures the residual energy of the battery 12. Details of the residual energy of the battery 12 are hereinafter described.

The sensor processing circuitry 15 performs sensing operation of transmitting observation data detected by the sensor 16 to the outside of the sensor node. The sensor processing circuitry 15 performs the sensing operation using electric energy supplied thereto from the battery 12 through the DCDC converter 14. The sensor processing circuitry 15 includes, for example, the sensor 16, MCU 17 and RF circuitry 18.

The sensor 16 detects given observation data such as a temperature. The MCU 17 includes a central processing unit (CPU), a ROM (Read Only Memory), a random access memory (RAM) and so forth and performs processing such as arithmetic operation. The RF circuitry 18 performs a modulation process and a demodulation process.

The MCU 17 acquires observation data detected by the sensor 16. The MCU 17 is a processing unit that performs a sensing operation of transmitting, if an observation data transmission request signal received by the antenna 19 is inputted to the MCU 17 through the RF circuitry 18, the observation data acquired from the sensor 16 from the antenna 19 through the RF circuitry 18. Accordingly, the management server 7 installed at a place spaced far away from the sensor nodes may collect observation data detected by the sensor nodes disposed in the individual areas by transmitting an observation data transmission request signal.

If a residual energy data transmission request signal received by the antenna 19 is inputted to the MCU 17 through the RF circuitry 18, the MCU 17 transmits residual energy data of the battery 12 measured by the battery's residual energy measurement circuit 30 from the antenna 19 through the RF circuitry 18. Accordingly, the management server 7 installed at a place spaced away from the sensor node may collect data of the residual energy of the battery 12 installed in the sensor node disposed in each area by transmitting a residual energy data transmission request signal. The battery's residual energy measurement circuit 30 or the MCU 17 may calculate a charging timing or a replacement timing of the battery 12 based on the measured residual energy of the battery 12. The MCU 17 may transmit from the antenna 19 a signal for the notification of a charging timing or a replacement timing of the battery 12 or a signal for the notification that the timing comes near or has passed.

The battery's residual energy measurement circuit 30 measures the residual energy of the battery 12. The battery's residual energy measurement circuit 30 includes, for example, a resistor 11, a Coulomb counter 13, a timer 26, a controller 28, a memory 29 and a switch 23. It is to be noted that “CC” in the figures represents an abbreviation of Coulomb counter.

The resistor 11 for current measurement is inserted in a current path 22 coupled to the battery 12. The Coulomb counter 13 measures current I flowing through the battery 12 (for example, current flowing along the current path 22) by measuring the potential difference ΔV appearing across the resistor 11 (I=ΔV/R). The character R represents a resistance value of the resistor 11.

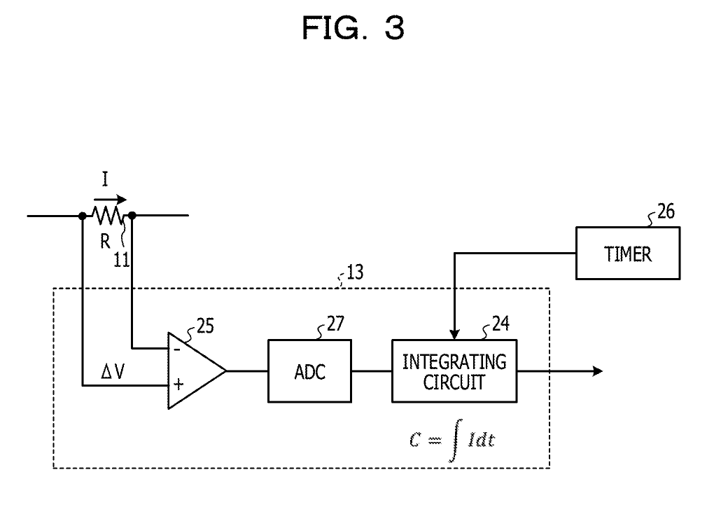

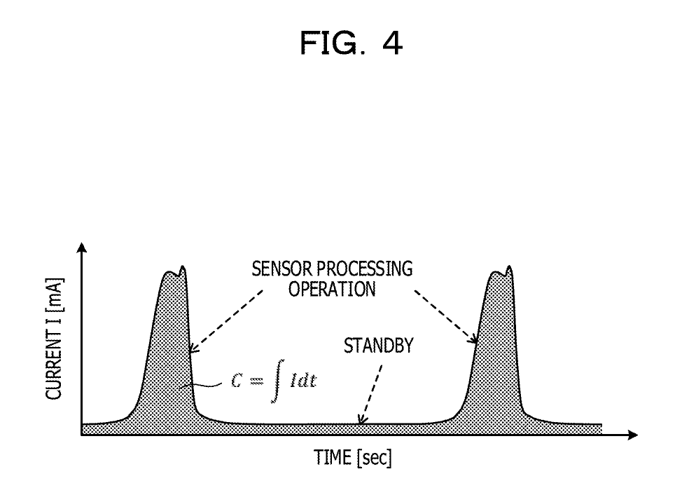

FIG. 3 is a view depicting an example of a configuration of the Coulomb counter. FIG. 4 is a view depicting an example of a waveform of the current I flowing through the resistor 11. The Coulomb counter 13 is an example of an integrated amount measurement circuitry that measures the integrated amount of current flowing through the battery. The Coulomb counter 13 includes, for example, an amplifier 25, an analog to digital converter (ADC) 27, and an integrating circuit 24. Since the potential difference AV in many cases appears as a very small potential difference, the amplifier 25 that amplifies the potential difference ΔV is used. The potential difference AV amplified by the amplifier 25 is converted from an analog value into a digital value by the ADC 27 and is time integrated by the integrating circuit 24. Consequently, the current I flowing through the battery 12 is integrated for a period measured by the timer 26, and an integrated amount of the current I (current integrated amount C) is calculated. The timer 26 is an example of time measurement circuitry that measures the time.

The controller 28 (refer to FIG. 2) may calculate a residual energy Cᵣ of the battery 12 by subtracting the grand total of the current integrated amount C (total current integrated amount Cₜₒₜₐₗ) from the capacity C_{bat} of the battery 12 (Cᵣ=C_{bat}−Cₜₒₜₐₗ).

However, the current consumption of the Coulomb counter 13 is comparatively high current (for example, approximately 100 μA). Therefore, a countermeasure is sometimes taken to suppress the current consumption to be used for measurement of the current integrated amount C by controlling the Coulomb counter 13 such that it does not operate normally but operates intermittently.

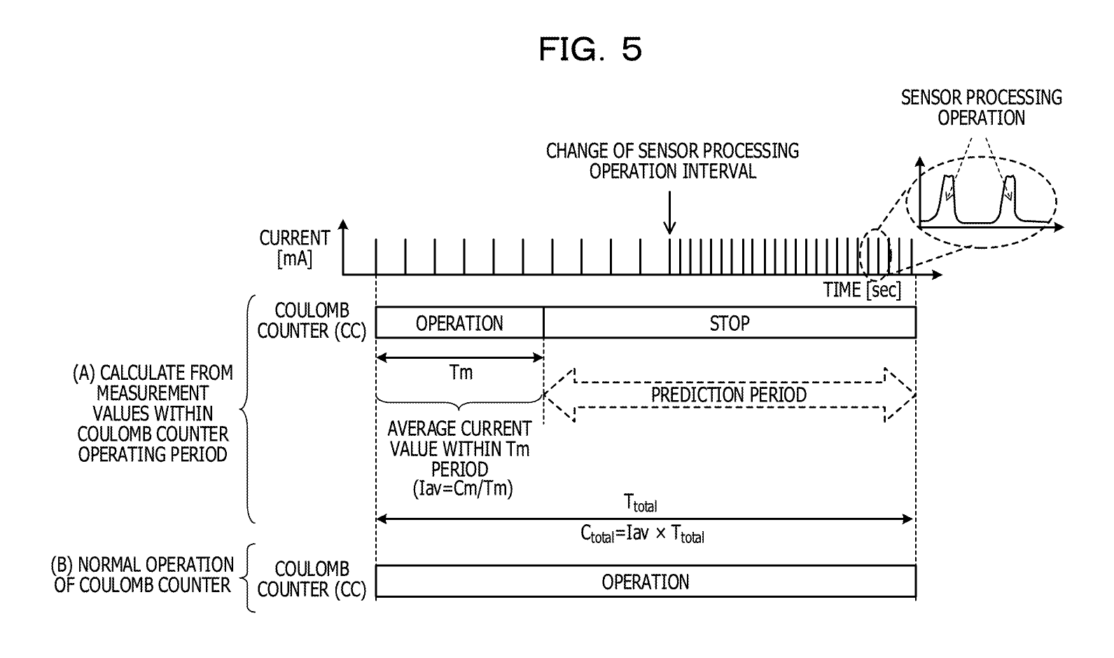

FIG. 5 is a view depicting an example of operation of a battery's residual energy measurement circuit in a comparative form. For example, the Coulomb counter 13 is controlled to operate only within a certain given time zone as indicated by (A) of FIG. 5. Average current Iav (=Cm/Tm) is calculated from the current integrated amount (Coulomb count amount Cm) measured in the time zone and the length of the time zone (count time Tm). Under the assumption that the average current lay continues to flow also within a period within which the Coulomb counter 13 stops, the controller 28 calculates the total current integrated amount Cₜₒₜₐₗ of the entire circuit in the total operating time Tₜₒₜₐₗ (Cₜₒₜₐₗ=Iav×Tₜₒₜₐₗ).

However, in the information collection system 1000, the collection frequency of observation data is sometimes changed dynamically in response to a change of the situation as described hereinabove. For example, the sewer flooding detection system mentioned hereinabove performs such control that information of the weather forecast on a web is acquired and, in a sunny weather in which the flooding risk is low, the observation data acquisition frequency is decreased to save the energy, and in contrast in a rainy weather in which the flooding risk is higher, the observation data acquisition frequency is increased.

Therefore, in the technique of (A) of FIG. 5, in the case where the interval between sensor processing operations (sensing operations) or the frequency of a sensor processing operation (sensing operation) is changed during a stopping period of the Coulomb counter 13, the calculated value of the average current lay and the actual value of average current becomes different by a great amount. Accordingly, there is the possibility that the calculation accuracy of the total current integrated amount Cₜₒₜₐₗ may degrade and the calculation accuracy of the residual energy of the battery 12 may degrade. In contrast, if the Coulomb counter 13 is controlled to operate normally as in the technique of (B) of FIG. 5 in order to improve the calculation accuracy of the residual energy of the battery 12, the current consumption used for measurement of the total current integrated amount Cₜₒₜₐₗ increases. In this manner, in the sensor node in the comparative form, a tradeoff occurs between the improvement of the calculation accuracy and the reduction of the current consumption of the battery's residual energy.

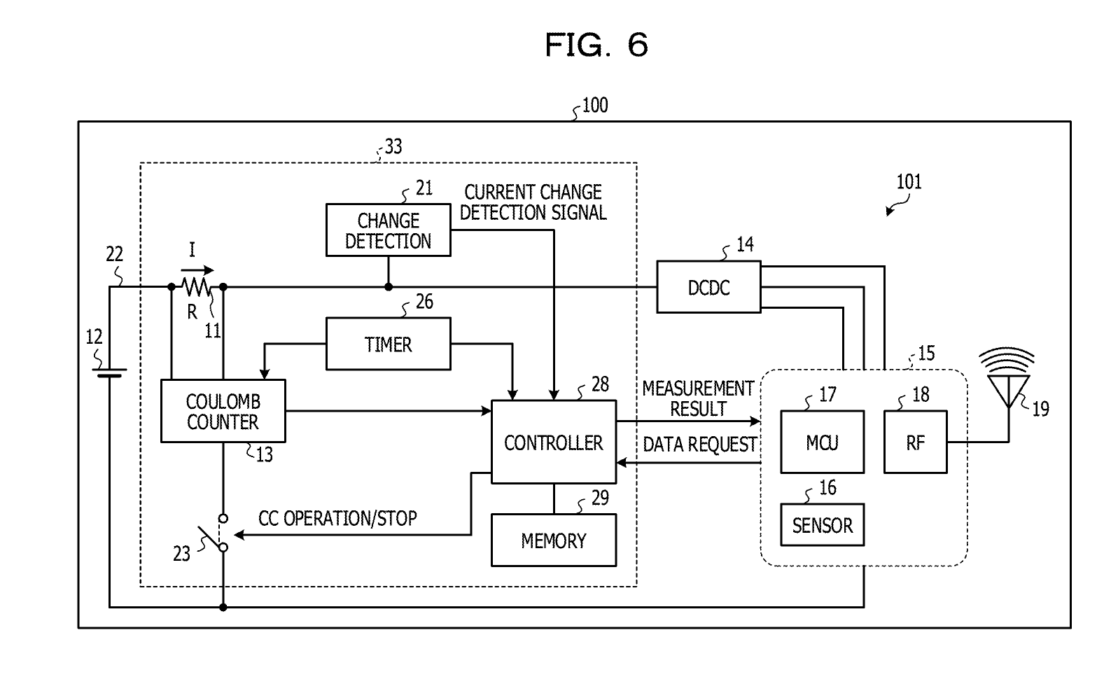

Therefore, in order to improve the calculation accuracy of the battery's residual energy, a sensor node 100 in the present embodiment depicted in FIG. 6 includes a battery's residual energy measurement circuit 33 that includes current change detection circuitry 21 that detects occurrence of a sensing operation that changes the current I. The sensor node 100 includes a control circuit 101 that includes at least the battery's residual energy measurement circuit 33 and the sensor processing circuitry 15. It is to be noted that, to description of components of the sensor node 100 of FIG. 6 same as those of the sensor node 10 of FIG. 2, the foregoing description is applied, and overlapping description of them is omitted.

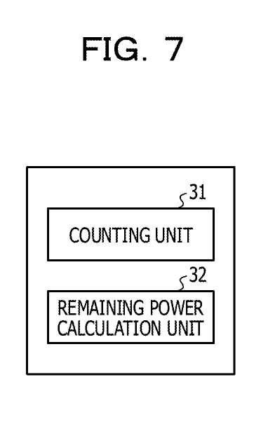

The current change detection circuitry 21 detects current I that changes, for example, in response to occurrence of a sensing operation and outputs a current change detection signal every time a change of the current I is detected. The controller 28 includes, as depicted in FIG. 7, counting circuitry 31 for counting the number of times by which the current change detection signal is outputted and a residual energy calculation circuitry 32 that calculates the residual energy of the battery 12 using the count value by the counting circuitry 31.

FIG. 7 is a view depicting an example of a functional configuration of the controller. The counting circuitry 31 is an example of time number measurement circuitry that measures the number of times by which a sensing operation that changes the current I occurs. The counting circuitry 31 is configured such that, for example, a plurality of flip-flops is coupled in series.

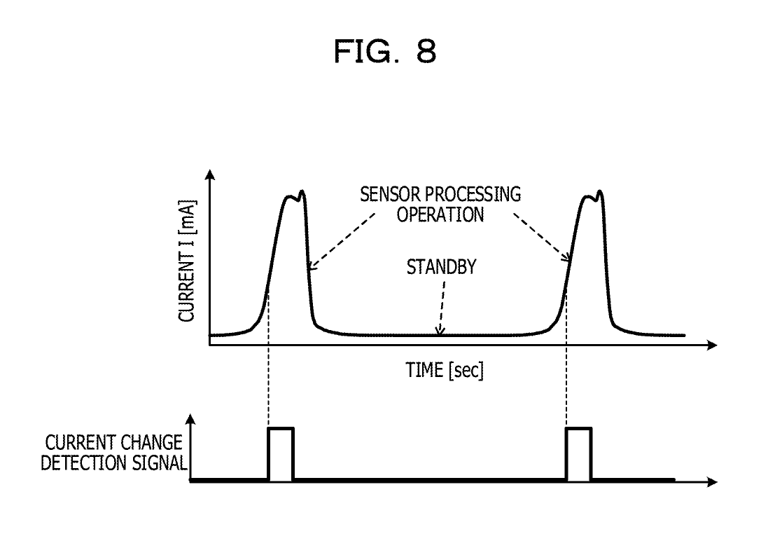

FIG. 8 is a view depicting an example a relation between a current waveform and a current change detection signal. For example, since the current I increases every time a sensing operation (sensor processing operation) occurs, also the current consumption of the sensor node 100 increases as depicted in FIG. 8. The current change detection circuitry 21 outputs a current change detection signal in the form of a pulse representing that occurrence of a sensing operation is detected by detecting a given increase of the current I. The counting circuitry 31 counts the number of times by which a sensing operation that changes the current I (sensing operation time number) occurs by counting the current change detection signal in the form of a pulse.

The residual energy calculation circuitry 32 (refer to FIG. 7) calculates the residual energy of the battery 12 using the current integrated amount measured within a measurement period T by the Coulomb counter 13, the sensing operation time number measured within the measurement period T by the counting circuitry 31 and the measurement period T measured by the timer 26.

The function of the residual energy calculation circuitry 32 is implemented by a CPU operating, for example, in accordance with a residual energy calculation processing program. The residual energy calculation processing program defines a procedure for causing the CPU to execute a process for calculating the residual energy of the battery 12. The controller 28 is, for example, a microcomputer that includes a CPU and a program saving memory that stores the residual energy calculation processing program.

Since the residual energy calculation circuitry 32 acquires the sensing operation time number measured within the measurement period T by the counting circuitry 31, it may recognize by what number of times current consumption by a sensing operation has occurred within the measurement period T within which the current integrated amount is measured by the Coulomb counter 13. Accordingly, the residual energy calculation circuitry 32 may calculate the residual energy of the battery 12 taking the current consumption amount generated in response to the sensing operation time number measured within the measurement period T by the counting circuitry 31 into account. Therefore, the calculation accuracy of the residual energy of the battery 12 may be improved.

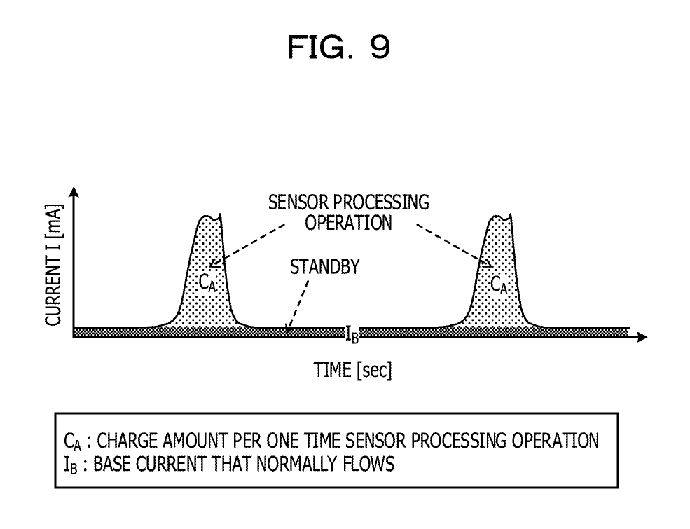

FIG. 9 is a waveform diagram depicting an example of a relation between charge C_{A} discharged from the battery 12 every time a sensing operation occurs once and base current I_{B} that normally flows out from the battery 12. As described hereinabove, in the case where the sensor node is controlled to intermittently execute a sensing operation only when needed, the current consumption of the sensor node may be reduced. In this case, the current integrated amount C measured by the Coulomb counter is separated into a component that relies upon the sensing operation time number (charge C_{A} discharged from the battery 12 every time a sensing operation occurs once) and a component that relies upon the time (base current I_{B} that normally flows out from the battery 12).

The charge C_{A} and the base current I_{B} are unknown parameters. Accordingly, if the unknown charge C_{A} and base current I_{B} may be presumed, the residual energy calculation circuitry 32 may calculate, even if the Coulomb counter 13 stops after the presumption, the residual energy Cᵣ of the battery 12 in accordance with the following relational expressions:

Cₜₒₜₐₗ=I_{B}×Tₜₒₜₐₗ+C_{A}×Nₜₒₜₐₗ (11)

Cᵣ=C_{bat}−Cₜₒₜₐₗ (12)

In the expression (11), Tₜₒₜₐₗ represents the total operating time of the sensor node (for example, elapsed time period after the base current I_{g} begins to flow), and Nₜₒₜₐₗ represents a total sensing operation time number (total number of times by which a sensing operation occurs within the total operating time Tₜₒₜₐₗ). Tₜₒₜₐₗ is measured by the timer 26, and Nₜₒₜₐₗ is measured by the counting circuitry 31. In the expression (12), C_{bat} represents the capacity of the battery 12, and Cₜₒₜₐₗ represents the total current integrated amount in the total operating time Tₜₒₜₐₗ.

In this manner, if the charge C_{A} and the base current I_{B} may be presumed, even if the measurement of the current integrated amount of the Coulomb counter 13 stops after the presumption of the charge C_{A} and the base current I_{B}, the residual energy calculation circuitry 32 may calculate the residual energy of the battery 12 using the measurement values of the timer 26 and the counting circuitry 31. Since the energy consumed by the Coulomb counter 13 decreases by stopping the measurement of the current integrated amount of the Coulomb counter 13, the current consumption of the sensor node may be reduced.

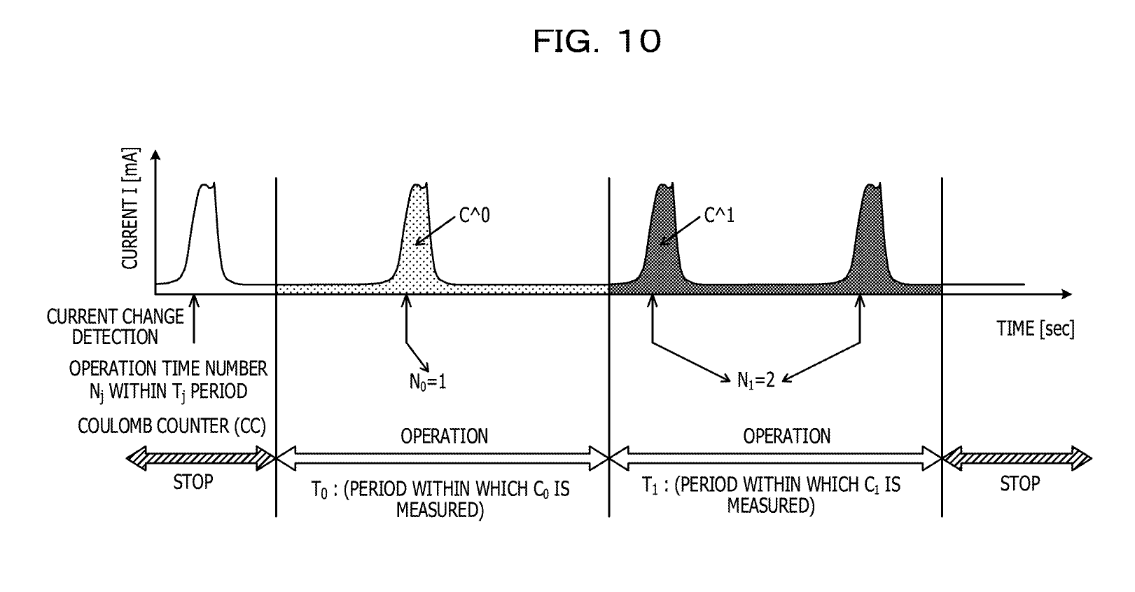

FIG. 10 is a view depicting a particular example of a calculation algorithm of battery's residual energy. FIG. 10 depicts a particular example of presumption of unknown charge C_{A} and base current I_{b} using the current integrated amounts and so forth measured by the Coulomb counter 13.

The residual energy calculation circuitry 32 acquires, during operation of the Coulomb counter 13, current integrated amounts (C₀, C₁, . . . ) separately within a plurality of measurement periods (T₀, T₁, . . . ) from the Coulomb counter 13 and acquires the sensing operation time numbers (N₀, N₁, . . . ) occurring in the measurement periods from the counting circuitry 31. Further, the residual energy calculation circuitry 32 acquires the plurality of periods (T₀, T₁, . . . ) from the timer 26. The residual energy calculation circuitry 32 derives the unknown charge C_{A} and base current I_{B} using the current integrated amounts (C₀, C₁, . . . ), sensing operation time numbers (N₀, N₁, . . . ) and measurement periods (T₀, T₁, . . . ).

Since basically the number of unknowns is two of C_{A} and I_{B}, the residual energy calculation circuitry 32 acquires the measurement values of the current integrated amount by the Coulomb counter 13 separately twice (C₀ and C₁) as depicted in FIG. 10. The residual energy calculation circuitry 32 acquires the measurement periods used for C₀ and C₁ as T₀ and T₁, respectively, from the timer 26. The residual energy calculation circuitry 32 acquires the sensing operation time number (N₀ and N₁) within the measurement period (T₀ and T₁) from the counting circuitry 31, respectively.

In each of the measurement periods, the following two expressions are satisfied:

I_{B}×T₀+C_{A}×N₀=C₀ (13)

I_{B}×T₁+C_{A}×N₁=C₁ (14)

The expression (13) signifies that the measured current integrated amount C₀ depends upon the sum of the current integrated amount I_{B}×T₀ that is the product of the base current I_{B} that flows normally and the measurement period T₀ and the current integrated amount C_{A}×N₀ that is the product of the charge C_{A} that is consumed per one time sensing operation and the operation time number N₀ of the sensing operation. This similarly applies also to the expression (14).

Since C₀, C₁, T₀, T₁, N₀ and N₁ are obtained from measurement results as described above, the residual energy calculation circuitry 32 may calculate C_{A} and I_{B} that are unknowns by solving the binary linear simultaneous equations of the expression (13) and the expression (14).

After C_{A} and I_{B} are calculated, the residual energy calculation circuitry 32 may calculate the residual energy Cᵣ of the battery 12 in accordance with the following relational expressions:

Cₜₒₜₐₗ=I_{B}×Tₜₒₜₐₗ+C_{A}×Nₜₒₜₐₗ (11)

Cᵣ=C_{bat}−Cₜₒₜₐₗ (12)

as described hereinabove. After C_{A} and I_{B} are calculated, since the current integrated amount measured by the Coulomb counter 13 is not used for a calculation process of the battery's residual energy by the expressions (11) and (12), the Coulomb counter 13 may be stopped.

Even after the Coulomb counter 13 stops, by causing the timer 26 and the counting circuitry 31 to normally operate, the residual energy calculation circuitry 32 may continuously calculate the residual energy Cᵣ of the battery 12 in accordance with the expressions (11) and (12). For example, even if the execute interval between sensing operations is changed after the Coulomb counter 13 stops, since the sensing operation time number may be counted accurately by the counting circuitry 31, the calculation accuracy of the battery's residual energy may be maintained high.

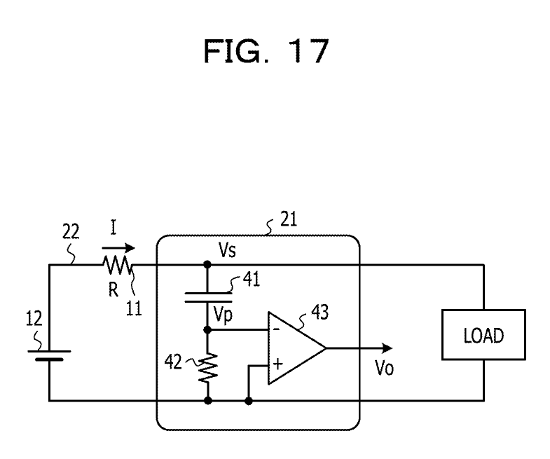

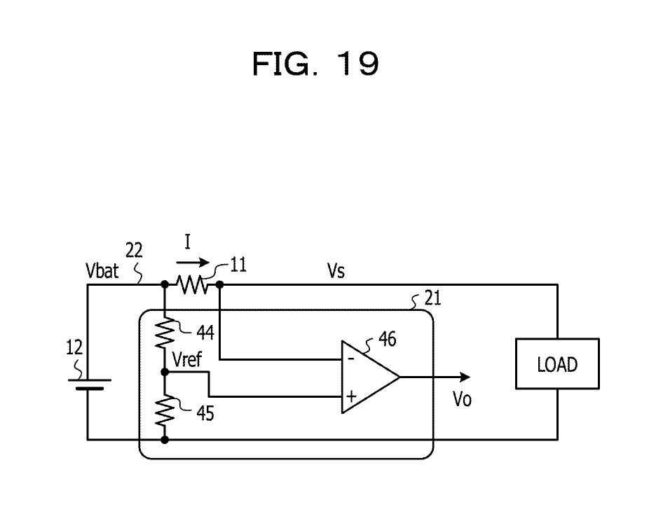

It is to be noted that the current consumption increases by an amount corresponding to the additionally provided current change detection circuitry 21. However, the current change detection circuitry 21 may be implemented by a simple circuit configuration only for acquiring information of whether the sensor processing circuitry 15 has operated (for example, refer to FIG. 17 or 19 hereinafter described). Therefore, the increasing amount of the current consumption is very small in comparison with the decreasing amount of the current consumption by stopping of the Coulomb counter 13.

In this manner, with the present embodiment, both high calculation accuracy of the battery's residual energy and reduction of the current consumption may be anticipated.

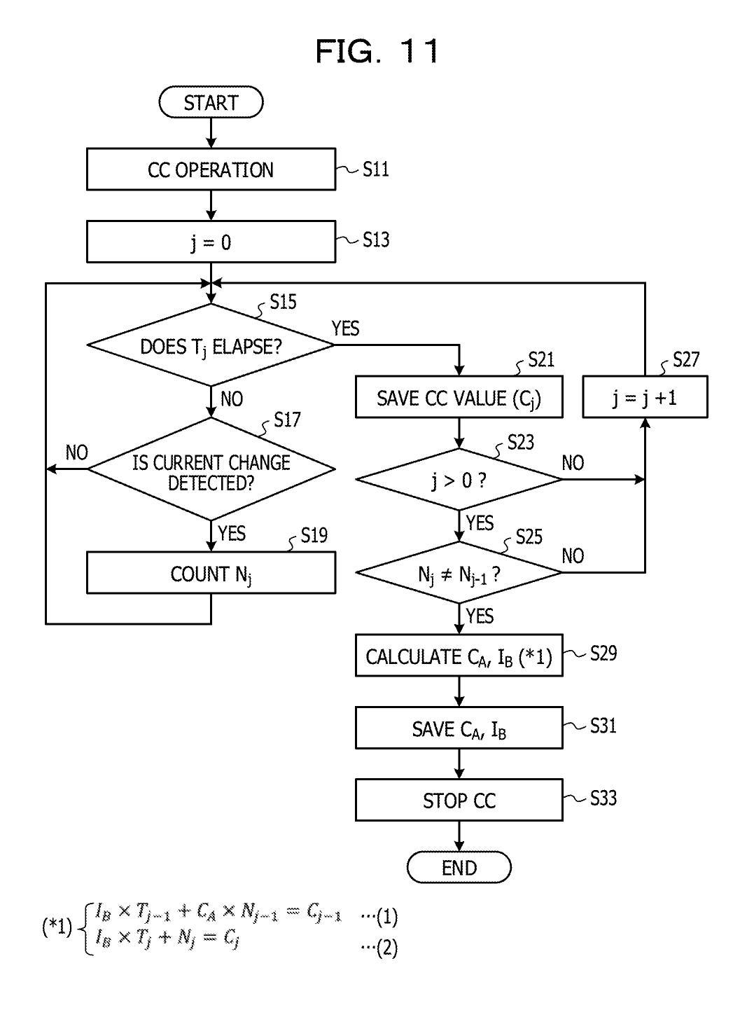

FIG. 11 is a flow chart depicting an example of a process for calculating and saving charge C_{A} and base current I_{B}. It is to be noted that, in the flow chart, “y” represents YES (affirmative) and “n” represents NO (negative).

At step S11, if an energy-on reset state is canceled by energy supply from the battery 12, the residual energy calculation circuitry 32 turns on the switch 23 (refer to FIG. 6). The switch 23 is inserted in series in the path along which energy supply current that is to flow through the Coulomb counter 13 passes. In response to turning on of the switch 23, operation of the Coulomb counter 13 is started.

At step S13, the residual energy calculation circuitry 32 initially sets a variable j to 0.

At step S15, the residual energy calculation circuitry 32 decides whether or not a measurement time Tⱼ elapses. In the case where the measurement time Tⱼ does not elapse, the residual energy calculation circuitry 32 acquires a sensing operation time number Nⱼ from the counting circuitry 31 (step S19). Every time a change of the current I caused by occurrence of a sensing operation is detected before the measurement time Tⱼ elapses, the counting circuitry 31 increments the sensing operation time number Nⱼ (step S17).

On the other hand, in the case where the residual energy calculation circuitry 32 decides at step S15 that the measurement time Tⱼ elapses, it acquires the current integrated amount Cⱼ measured within the measurement time Tⱼ by the Coulomb counter 13 from the Coulomb counter 13 and saves the current integrated amount Cⱼ into the memory 29 (refer to FIG. 6) (step S21).

The residual energy calculation circuitry 32 decides whether or not j is greater than 0 (step S23), and in the case where j is not greater than 0, the residual energy calculation circuitry 32 increments j (step S27) and performs the process at step S15 again. On the other hand, in the case where it is decided that j is greater than 0, the residual energy calculation circuitry 32 decides whether or not the sensing operation time number Nⱼ within the measurement time Tⱼ is different from the sensing operation time number Nⱼ₋₁ within measurement time Tⱼ₋₁ (step S25).

In the case where Nⱼ is not different from (is substantially equal to) Nⱼ₋₁, the residual energy calculation circuitry 32 increments j (step S27) and performs the process at step S15 again. On the other hand, in the case where Nⱼ and Nⱼ₋₁ are different from each other, the residual energy calculation circuitry 32 solves the simultaneous equations of the expression (*1) to calculate the charge C_{A} and the base current I_{B} (step S29). In the case where the measurement periods Tⱼ (j is an integer equal to or greater than 0) are fixed, it is difficult to solve the simultaneous equation of the expression (*1) unless data that are different in sensing operation time number N from each other are measured. Accordingly, measurement of the sensing operation time number N is continued until data having a difference in sensing operation time number N from each other are measured (for example, the decision of Yes is made at step S25).

At step S31, the residual energy calculation circuitry 32 saves the charge C_{A} and the base current I_{B} calculated at step S29 into the memory 29. At step S33, the residual energy calculation circuitry 32 turns off the switch 23 after it saves the charge C_{A} and the base current I_{B} into the memory 29. When the switch 23 is switched off, the operation of the Coulomb counter 13 stops.

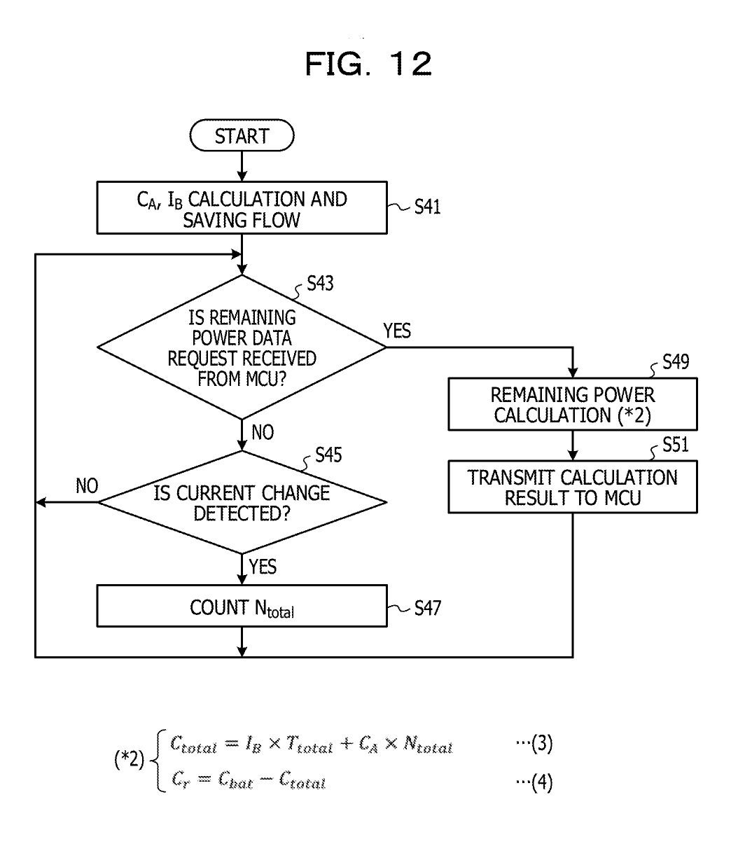

FIG. 12 is a flow chart depicting a first operation example of a battery's residual energy measurement circuit. In the first operation example, the residual energy calculation circuitry 32 first calculates and saves C_{A} and I_{B} once upon starting operation of the sensor node and then stops the Coulomb counter 13. After the stopping of the Coulomb counter 13, every time a residual energy data request is received from the MCU 17 of the sensor processing circuitry 15, the residual energy calculation circuitry 32 uses saved C_{A} and I_{B} to calculate Cₜₒₜₐₗ and Cᵣ and transmits a result of the calculation to the MCU 17.

Step S41 represents the flow depicted in FIG. 11. At step S43, the residual energy calculation circuitry 32 decides whether or not a residual energy data request from the MCU 17 is received. In the case where a residual energy data request is not received, the residual energy calculation circuitry 32 acquires a total sensing operation time number Nₜₒₜₐₗ from the counting circuitry 31 (step S47). The counting circuitry 31 increments the total sensing operation time number Nₜₒₜₐₗ every time a change of the current I caused by occurrence of a sensing operation is detected until a residual energy request is received (step S45).

On the other hand, in the case where it is decided at step S43 that a residual energy data request is received, the residual energy calculation circuitry 32 calculates the residual energy Cᵣ of the battery 12 in accordance with the expression (*2) (step S49) and transmits a result of the calculation to the MCU 17 (step S51).

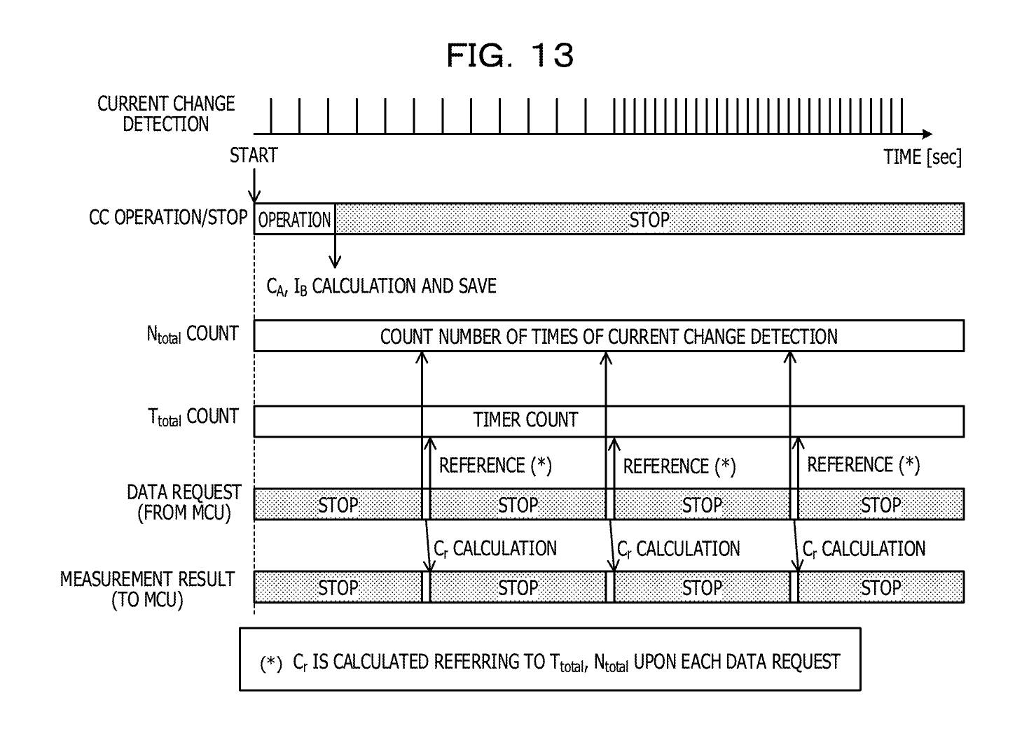

FIG. 13 is a time chart depicting the first operation example of the battery's residual energy measurement circuit. The residual energy calculation circuitry 32 stops the Coulomb counter 13 after it calculates and saves C_{A} and I_{B} once upon starting of operation of the sensor node. The counting circuitry 31 continues to normally count the total sensing operation time number Nₜₒₜₐₗ and the timer 26 continues to normally count the total operating time Tₜₒₜₐₗ. At the timing at which a residual energy data request is received from the MCU 17, the residual energy calculation circuitry 32 calculates the residual energy Cᵣ of the battery 12 in accordance with the expression (*2) using Nₜₒₜₐₗ and Tₜₒₜₐₗ at the timing and transmits the residual energy Cᵣ that is a result of the calculation to the MCU 17.

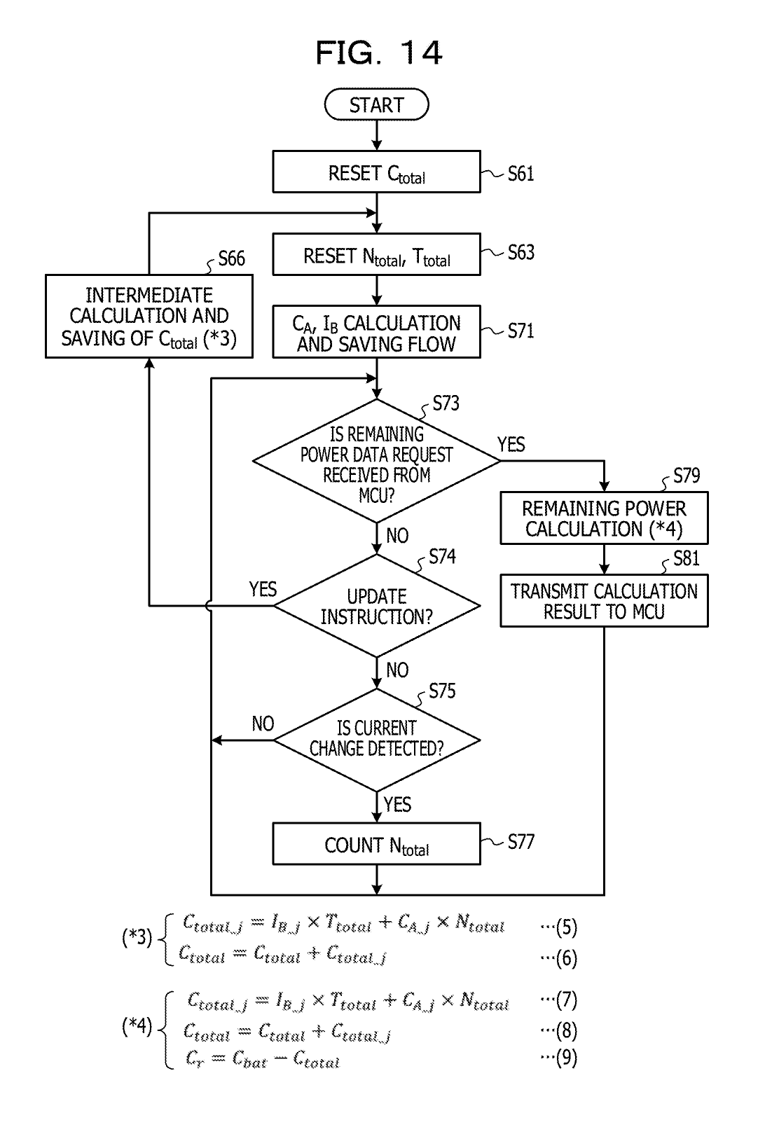

In the first operation example depicted in FIGS. 12 and 13, upon starting of operation of the sensor node, C_{A} and I_{B} are calculated once and saved, and calculation of the battery's residual energy continues using saved C_{A} and I_{B}. However, actually C_{A} and I_{B} are in many cases varied by a change of the environment. Therefore, an example is conceivable in which, in response to occurrence of a given event, the residual energy calculation circuitry 32 calculates C_{A} and I_{B} again and performs updating of saved C_{A} and I_{B} using them. The given event occurs, for example, periodically or in response to a temperature variation. FIGS. 14 to 16 depict examples in which C_{A} and I_{B} are calculated again and used for updating.

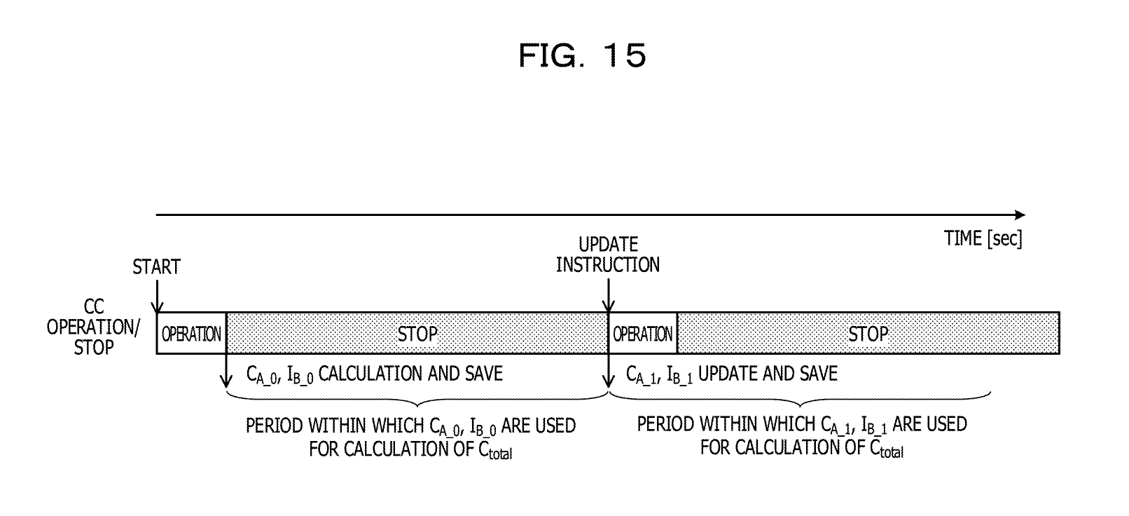

FIG. 14 is a flow chart depicting a second operation example of the battery's residual energy measurement circuit. FIG. 15 is a time chart depicting the second operation example of the battery's residual energy measurement circuit. In the second operation example, at a point of time at which an updating instruction is received, operation of the Coulomb counter 13 that is in a stopping station is re-started to render the C_{A} and I_{B} calculation and save flow of FIG. 11 to update C_{A} and I_{B}. After the updating, the updated values are used to calculate the battery's residual energy. The second operation example is different from the first operation example in that the C_{A} and I_{B} calculation and saving flow of FIG. 11 is rendered operative upon reception of an updating instruction in addition to upon starting of operation of the sensor node.

At step S61, the residual energy calculation circuitry 32 resets the total current integrated amount Cₜₒₜₐₗ. At step S63, the residual energy calculation circuitry 32 resets the total sensing operation time number Nₜₒₜₐₗ and the total operating time Tₜₒₜₐₗ.

At step S71, the residual energy calculation circuitry 32 executes the C_{A} and I_{B} calculation and saving flow of FIG. 11.

At step S73, the residual energy calculation circuitry 32 decides whether or not a residual energy data request from the MCU 17 is received. If a residual energy data request is not received, the residual energy calculation circuitry 32 decides whether or not an updating instruction from the MCU 17 is received (step S74). In the case where an updating instruction is not received, the residual energy calculation circuitry 32 acquires the total sensing operation time number Nₜₒₜₐₗ from the counting circuitry 31 (step S77). The counting circuitry 31 increments the total sensing operation time number Nₜₒₜₐₗ every time a change of the current I caused by occurrence of a sensing operation is detected until an updating instruction is received (step S75).

On the other hand, if the residual energy calculation circuitry 32 decides at step S74 that an updating instruction is received, it calculates intermediate data of the total current integrated amount Cₜₒₜₐₗ in accordance with the expression (*3) and temporarily saves the calculated intermediate data into the memory 29 (step S66).

For example, in the case where an i+1th updating instruction is received at step S74, the residual energy calculation circuitry 32 calculates, before it calculates C_{A}_{_}ᵢ₊₁ and I_{B}_{_}ᵢ₊₁, the total current integrated amount Cₜₒₜₐₗ_{_}ᵢ using data (C_{A}_{_}ᵢ and I_{B}_{_}ᵢ) of the ith charge and base current. Then, the residual energy calculation circuitry 32 sums calculated Cₜₒₜₐₗ_{_}ᵢ to Cₜₒₜₐₗ till the i−1th updating instruction. Thereafter, the residual energy calculation circuitry 32 resets Tₜₒₜₐₗ and Nₜₒₜₐₗ at step S63 and enters a calculation flow for the i+1th updating instruction. The variable i represents an integer equal to or greater than 0.

On the other hand, in the case where the residual energy calculation circuitry 32 decides at step S73 that a residual energy data request is received, it calculates Cₜₒₜₐₗ_{_}ᵢ using C_{A}_{_}ᵢ, I_{B}_{_}ᵢ, Tₜₒₜₐₗ and Nₜₒₜₐₗ at the point of time in accordance with the expression (7) of the expression (*4). The residual energy calculation circuitry 32 sums calculated Cₜₒₜₐₗ_{_}i to Cₜₒₜₐₗ until then by the expression (8) and calculates residual energy Cᵣ by the expression (9) (step S79). At step S81, the residual energy calculation circuitry 32 transmits the residual energy Cᵣ of a result of the calculation to the MCU 17.

It is to be noted that, although only an operating period and a stopping period of the Coulomb counter are depicted in FIG. 15, in the entire time chart, portions other than the operation/stopping of the Coulomb counter are similar to those in FIG. 13.

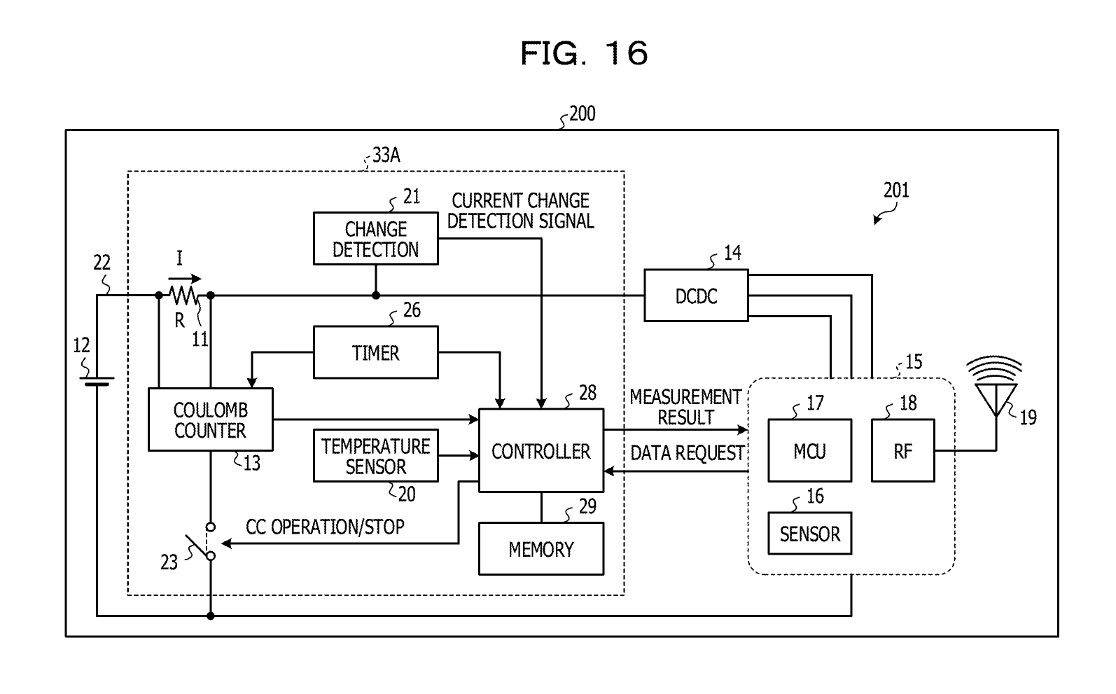

The updating instruction may be generated periodically using the timer 26 or may be generated in response to occurrence of a temperature change by a given temperature change amount. FIG. 16 depicts an example of a configuration of a sensor node in a second embodiment in which an updating instruction is generated using a temperature change as a trigger. The sensor node 200 includes a control circuit 201 that includes at least a battery's residual energy measurement circuit 33A and a sensor processing circuitry 15. The battery's residual energy measurement circuit 33A includes a temperature sensor 20 that measures an ambient temperature.

The base current I_{B} varies by a great amount in response to a temperature change. Therefore, an updating instruction is outputted at a level at which the variation amount of I_{B} by a temperature change does not have a bad influence on the calculation accuracy of the battery's residual energy. If the change amount of the temperature measured by the temperature sensor 20 exceeds a given amount, an updating instruction of C_{A} and I_{B} is generated.

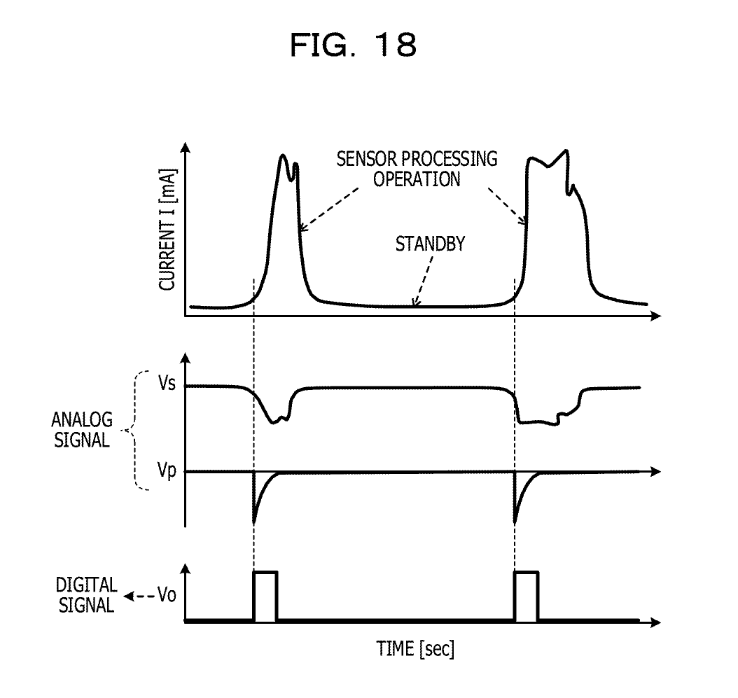

FIG. 17 is a view depicting a first configuration example of current change detection circuitry. FIG. 18 is a view depicting an example of operation waveforms in the first configuration example of the current change detection circuitry. The current change detection circuitry 21 of FIG. 17 includes a bypass filter including a series circuit of a capacitor 41 and a resistor 42, and a comparator 43. Since the current I increases by occurrence of a sensing operation, the voltage drop amount by the resistor 11 dynamically increases and the measurement voltage Vs at the measurement point on the downstream with respect to the resistor 11 decreases. If the measurement voltage Vs decreases suddenly, since the analog voltage Vp decreases suddenly, the comparator 43 detects the sudden decrease of the analog voltage Vp as occurrence of a sensing operation. If the comparator 43 detects occurrence of a sensing operation, it outputs a pulse signal Vo of the high level as a digital signal. Since the current change detection circuitry may be implemented by such a simple configuration as just described, even if it is normally kept operative, the current consumption may be suppressed to approximately 1 μA.

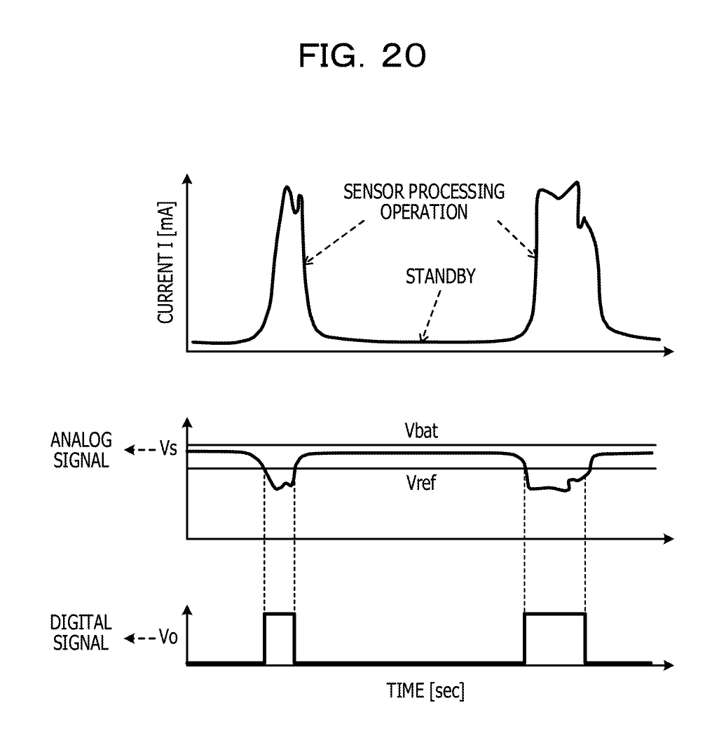

FIG. 19 is a view depicting a second configuration example of the current change detection circuitry. FIG. 20 is a view depicting an example of operation waveforms in the second configuration example of the current change detection circuitry. The current change detection circuitry 21 of FIG. 19 includes a reference voltage generation circuit including a series circuit of a resistor 44 and another resistor 45, and a comparator 46. A reference voltage Vref lower than the battery voltage Vbat is generated by voltage division of the battery voltage Vbat by the resistors 44 and 45. When the measurement voltage Vs that varies depending upon the magnitude of the current I becomes lower than the reference voltage Vref, it is regarded that a sensing operation is performed, and the comparator 46 outputs a pulse signal Vo of the high level. On the other hand, when the measurement voltage Vs becomes higher than Vref, it is regarded that a standby state is entered, and the comparator 46 outputs the pulse signal Vo of the low level. Although the circuit that generates the reference voltage Vref by resistor voltage division normally consumes current, the current consumption value is suppressed to approximately 1 μA or less.

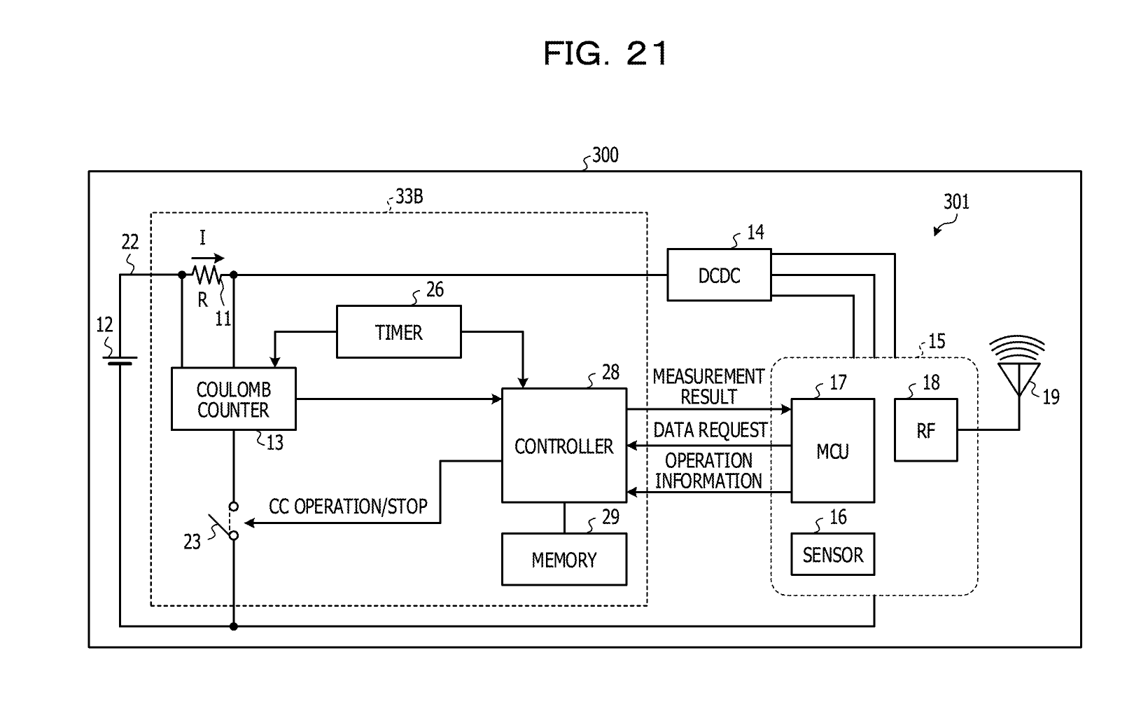

FIG. 21 is a view depicting an example of a configuration of a sensor node in a third embodiment. In the first embodiment of FIG. 6, in order to detect a timing at which a sensor processing operation is to be performed, the current change detection circuitry 21 is provided. In contrast, the sensor node 300 in the third embodiment of FIG. 21 includes a configuration that may receive operation information representative of occurrence of a sensing operation from the MCU 17 of the sensor processing circuitry 15. The MCU 17 transmits the operation information to the battery's residual energy measurement circuit 33B every time it performs a sensing operation. The sensor node 300 includes a control circuit 301 that includes at least the battery's residual energy measurement circuit 33B and the sensor processing circuitry 15. The counting circuitry 31 in the controller 28 may measure the number of times by which a sensing operation occurs by counting the operation information. In this case, the current change detection circuitry 21 in the first embodiment becomes unnecessary, and the counting circuitry 31 may count the sensing operation time number based on the operation information from the MCU 17. The configuration of the other part of the sensor node is same as that in the embodiments described hereinabove, and similar advantageous effects may be achieved also with the third embodiment.

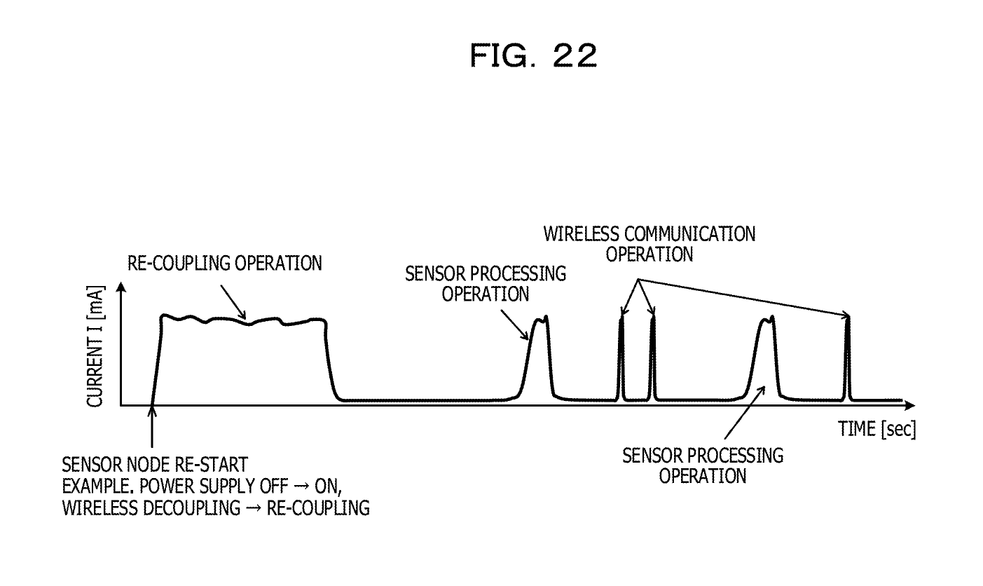

Incidentally, the sensor node repeats a sensor processing operation (sensing operation) simply and, in addition thereto, sometimes performs at least one operation different from the sensor processing operation. FIG. 22 is a view depicting an example of an operation waveform of a sensor node. For example, as depicted in FIG. 22, the sensor node sometimes performs, when communication with a gateway is interrupted (re-coupling operation), an operation for assuring communication again or a wireless communication operation called keep alive independently of the sensor processing operation in order to maintain a communication state. Since such operations are different in current consumption value upon operation from the sensor processing operation and consume different charge amounts, if the charge amount per one time operation is defined simply as C_{A} as described hereinabove, it is supposed that a significant measurement error may occur. Now, a second residual energy calculation method for distinguishing the operations from one another to calculate a battery's residual energy.

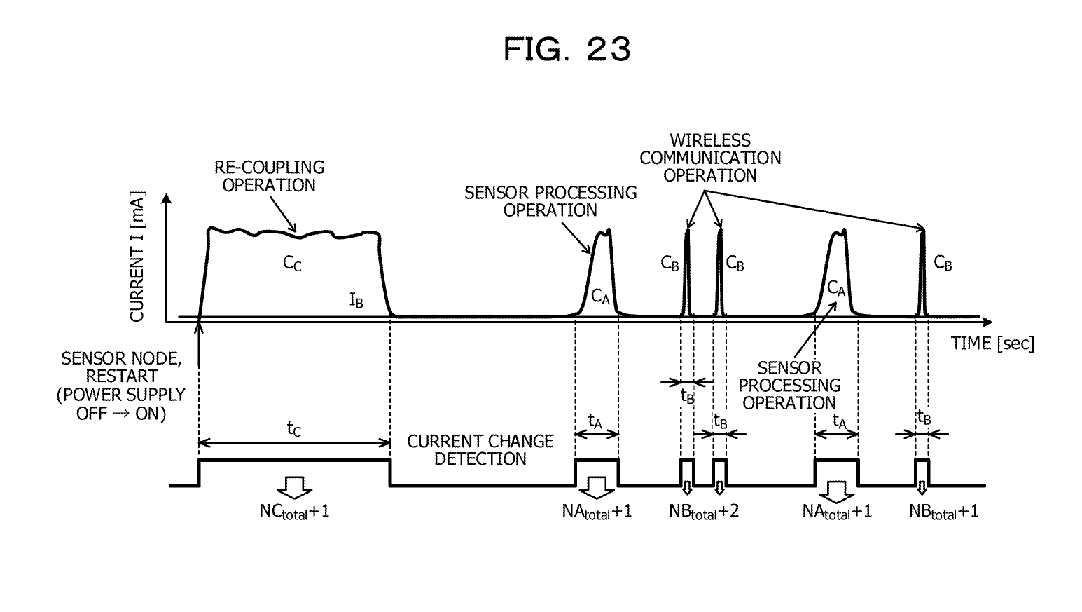

FIG. 23 is a view depicting a second particular example of a relation between a current waveform and a current change detection signal. FIG. 23 depicts a method of defining charge consumption amounts, which are discharged from the battery 12 per one time occurrence of the sensor processing operation, wireless communication operation and re-coupling operation each, separately like C_{A}, C_{B} and C_{C}. Although the total number of unknowns is four including the base current IB that normally flows out from the battery 12, if quaternion simultaneous equations are established and solved, the four unknowns C_{A}, C_{B}, C_{C} and I_{B} may be calculated.

The individual operations may be discriminated, for example, based on a difference in length of a period of time within which an operation that changes the current (period of time within which a current change is detected). For example, since the re-coupling operation continues in circuitry of several tens of seconds and the sensor processing operation continues in circuitry of one second while the wireless communication operation continues in circuitry of several tens of milliseconds, each of the operations may be discriminated readily depending upon the length of the period of time within which a current change is detected.

For example, the current change detection circuitry 21 described above with reference to FIG. 6 and so forth is configured such that it may acquire change starting time and change ending time of the current I that changes together with occurrence of each operation. The time difference between the change starting time and the change ending time in the re-coupling operation is represented by t_{C}, the time difference between the change starting time and the change ending time in the sensor processing operation is represented by t_{A}, and the time difference between the change starting time and the change ending time in the wireless communication operation is represented by t_{B} (refer to FIG. 23). They have, for example, a relation that t_{C} is greater than t_{A} and t_{A} is greater than t_{B}. The counting circuitry 31 decides based on a difference in length of the current change detection signal in the form of a pulse (refer to FIGS. 19 and 20) outputted from the current change detection circuitry 21 which one of the sensor processing operation, wireless communication operation and re-coupling operation occurs. Then, the counting circuitry 31 counts the number of times by which each operation occurs (number of times of occurrence of each operation). The counting circuitry 31 includes a plurality of counters (NA, NB and NC) for the individual operations and may increment, after discrimination of an operation, the counter corresponding to the discriminated operation.

Then, if the four unknowns C_{A}, C_{B}, C_{C} and I_{B} are calculated, the residual energy calculation circuitry 32 may calculate the residual energy Cᵣ of the battery 12 in accordance with the following relational expressions:

Cₜₒₜₐₗ=I_{B}×Tₜₒₜₐₗ+C_{A}×NAₜₒₜₐₗ+C_{B}×NBₜₒₜₐₗ+C_{C}×NCₜₒₜₐₗ (21)

Cᵣ=C_{bat}−Cₜₒₜₐₗ (22)

In the expression (21), Tₜₒₜₐₗ represents a total operating time of the sensor node (for example, an elapsed time period after the base current I_{B} begins to flow), and NAₜₒₜₐₗ represents a total sensing operation time number (a total number of times by which a sensing operation occurs within the total operating time Tₜₒₜₐₗ). NBₜₒₜₐₗ represents a total wireless communication operation time number (a total number of times by which a wireless communication operation occurs within the total operating time Tₜₒₜₐₗ), and NCₜₒₜₐₗ represents a total re-coupling operation time number (a total number of times by which a re-coupling operation occurs within the total operating time Tₜₒₜₐₗ). Tₜₒₜₐₗ is measured by the timer 26, and NAₜₒₜₐₗ, NBₜₒₜₐₗ and NCₜₒₜₐₗ are measured by the respective counters in the counting circuitry 31. In the expression (22), C_{bat} represents the capacity of the battery 12, and Cₜₒₜₐₗ represents the total current integrated amount in the total operating time Tₜₒₜₐₗ.

Since the battery's residual energy may be calculated while the difference in operation state of the sensor node is discriminated in this manner, higher measurement accuracy may be ensured. Further, even if the number of types of operation states increases, basically this merely increases the number of unknowns to be defined, and since the number of unknowns in simultaneous equations to be prepared may be increased as much, the scalability is high.

Further, the controller 28 may decide a difference in operation state of the sensor node based on the difference in length of a period of time within which a current change continues to be detected. Therefore, even if the controller 28 does not acquire operation information representative of occurrence of a re-coupling operation from the MCU 17, the controller 28 may operate the Coulomb counter 13 within an occurrence period of a re-coupling operation to measure a current integrated amount caused by the re-coupling operation and may utilize the measurement value for calculation of the battery's residual energy. Similarly, even if the controller 28 does not acquire operation information representative of occurrence of a wireless communication operation from the MCU 17, the controller 28 may operate the Coulomb counter 13 within an occurrence period of the wireless communication operation to measure a current integrated amount caused by the wireless communication operation and may utilize the measurement value for calculation of the battery's residual energy.

Further, similarly as in the residual energy calculation method described above, if C_{A}, C_{B}, C_{C} and I_{B} may be estimated, even if measurement of the current integrated amount of the Coulomb counter 13 stops after estimation of C_{A}, C_{B}, C_{C} and I_{B}, the residual energy calculation circuitry 32 may calculate the residual energy of the battery 12 using the measurement values of the timer 26 and the counting circuitry 31. By stopping the measurement of the current integrated amount of the Coulomb counter 13, the energy consumed by the Coulomb counter 13 decreases, and therefore, the current consumption of the sensor node may be reduced.

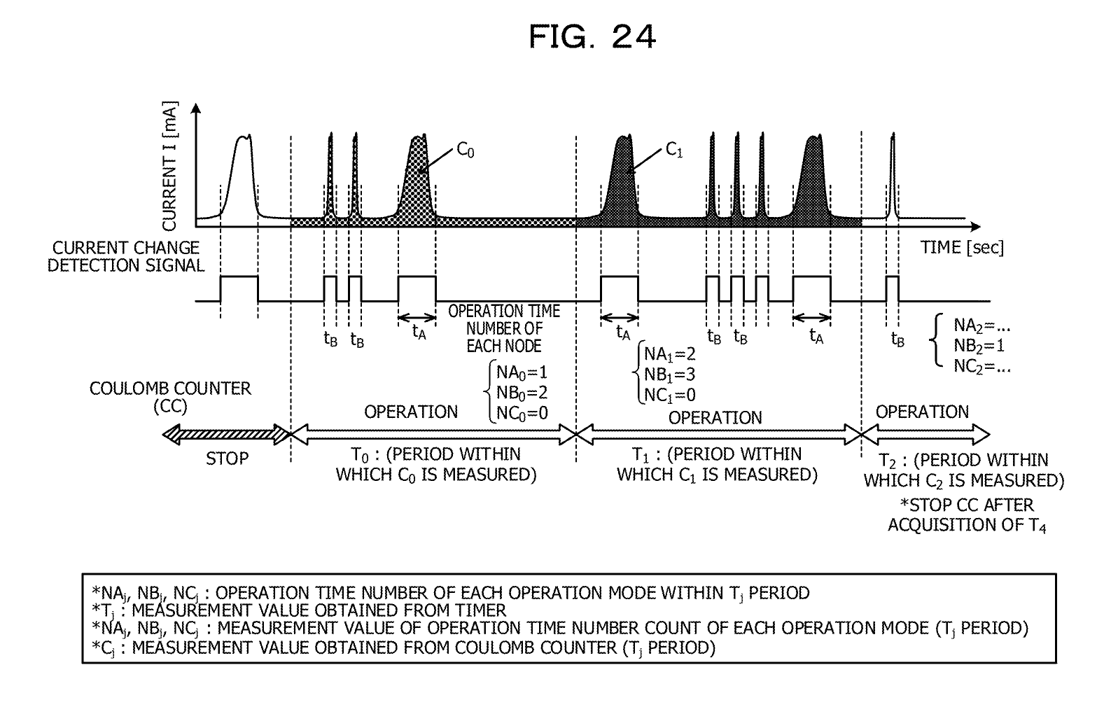

FIG. 24 is a view depicting a second particular example of the calculation algorithm of the battery's residual energy. FIG. 24 depicts a particular example for calculating the four unknowns C_{A}, C_{B}, C_{C} and I_{B} from measurement values of the Coulomb counter.

Basically, since the way of thinking is similar to that described hereinabove with reference to FIG. 10 and the number of unknowns is four including C_{A}, C_{B}, C_{C} and I_{B}, the residual energy calculation circuitry 32 acquires measurement values of the current integrated amount by the Coulomb counter 13 separately at least four times (C₀, C₁, C₂ and C₃) during operation of the Coulomb counter 13 as depicted in FIG. 24. The residual energy calculation circuitry 32 acquires measurement time periods T₀, T₁, T₂ and T₃ used for C₀, C₁, C₂ and C₃, respectively, from the timer 26. The residual energy calculation circuitry 32 acquires the operation time number of each operation mode (re-coupling operation, sensor processing operation and wireless communication operation) in the measurement time periods T₀, T₁, T₂ and T₃, respectively, from the counting circuitry 31. The operation time numbers of the operation modes in the measurement time periods T₀, T₁, T₂ and T₃ are NA₀, NB₀ and NC₀ in the period T₀, NA₁, NB₁ and NC₁ in the period T₁, NA₂, NB₂ and NC₂ in the period T₂ and NA₃, NB₃ and NC₃ in the period T₃.

In each of the measurement time periods, the following four expressions are satisfied:

I_{B}×T₀+C_{A}×NA₀+C_{B}×NB₀+C_{C}×NC₀=C₀ (23)

I_{B}×T₁+C_{A}×NA₁+C_{B}×NB₁+C_{C}×NC₁=C₁ (24)

I_{B}×T₂+C_{A}×NA₂+C_{B}×NB₂+C_{C}×NC₂=C₂ (25)

I_{B}×T₃+C_{A}×NA₃+C_{B}×NB₃+C_{C}×NC₃=C₃ (26)

The expression (23) signifies that the measured current integrated amount C₀ depends upon the sum of the current integrated amount I_{B}×T₀, current integrated amount C_{A}×NA₀, current integrated amount C_{B}×NB₀ and current integrated amount C_{C}×NC₀. This similarly applies also to the expressions (24) to (26).

Since Cⱼ, Tⱼ, NAⱼ, NBⱼ and NCⱼ are obtained from measurement results as described hereinabove (j=0, 1, 2, 3), the residual energy calculation circuitry 32 may calculate the unknowns C_{A}, C_{B}, C_{C} and I_{B} by solving the quaternion simultaneous equations by the expressions (23) to (26).

If C_{A}, C_{B}, C_{C} and I_{B} are solved, the residual energy calculation circuitry 32 may calculate the residual energy Cᵣ of the battery 12 in accordance with the relational expressions:

Cₜₒₜₐₗ=I_{B}×Tₜₒₜₐₗ+C_{A}×NAₜₒₜₐₗ+C_{B}×NBₜₒₜₐₗ+C_{C}×NCₜₒₜₐₗ (21)

Cᵣ=C_{bat}−Cₜₒₜₐₗ (22)

given herein above. After C_{A}, C_{B}, C_{C} and I_{B} are calculated, the Coulomb counter 13 may be stopped because the current integrated amounts measured by the Coulomb counter 13 are not thereafter used for a calculation process of the battery's residual energy by the expressions (21) and (22).

Even after the Coulomb counter 13 stops, since the timer 26 and the counting circuitry 31 operate normally, the residual energy calculation circuitry 32 may continuously calculate the residual energy Cᵣ of the battery 12 in accordance with the expressions (21) and (22). For example, even if the execution interval of operations such as a sensing operation is changed after stopping of the Coulomb counter 13, since the operation time number of each operation may be counted accurately by the counting circuitry 31, the calculation accuracy of the battery's residual energy may be maintained high.

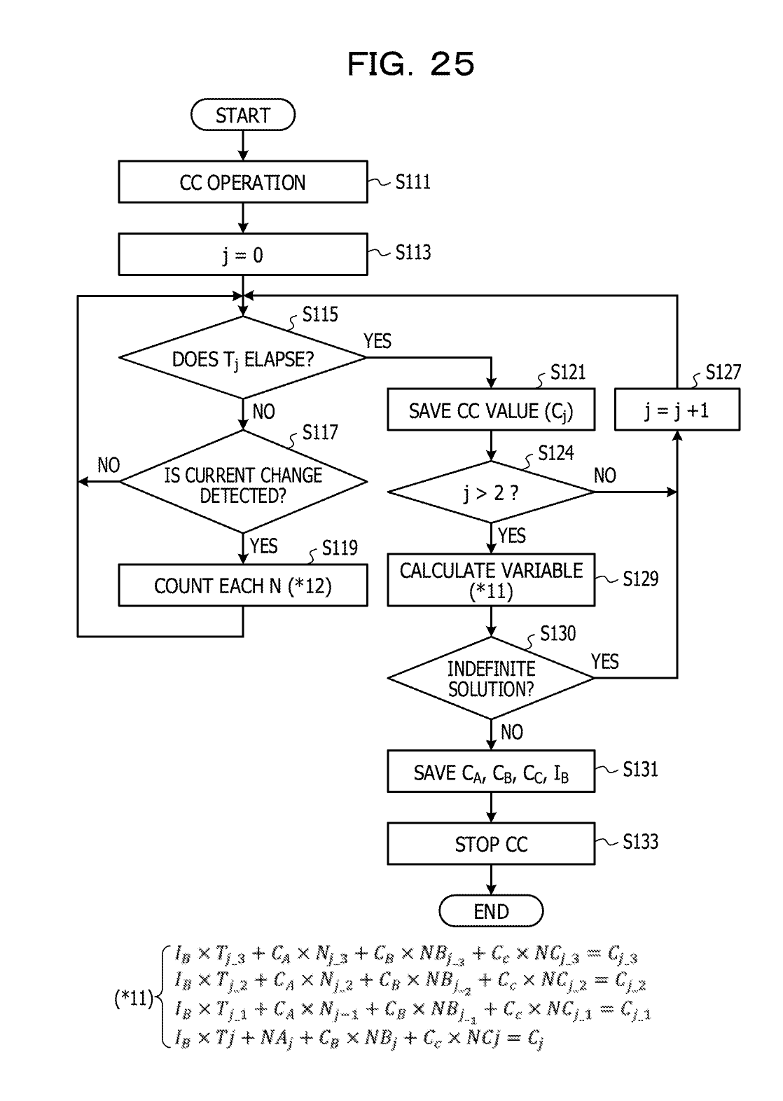

FIG. 25 is a flow chart depicting an example of a process for calculating and saving C_{A}, C_{B}, C_{C} and I_{B}. Since the way of thinking here is basically similar to that depicted in FIG. 11, in FIG. 25, N counting circuitry (NA, NB and NC) that decide and count three operation states are newly added and a modification is applied to solve four unknowns from quaternion simultaneous equations.

If the energy-on reset is canceled by energy supply from the battery 12, the residual energy calculation circuitry 32 turns on the switch 23 (refer to FIG. 6) at step S111. The switch 23 is inserted in series in the path along which energy supply current to flow to the Coulomb counter 13 passes. In response to turning on of the switch 23, operation of the Coulomb counter 13 is started.

At step S113, the residual energy calculation circuitry 32 initially sets the variable j to 0.

At step S115, the residual energy calculation circuitry 32 decides whether or not the measurement time Tⱼ elapses. In the case where the measurement time Tⱼ does not elapse, the residual energy calculation circuitry 32 acquires the operation time numbers NAⱼ, NBⱼ and NCⱼ of the individual operations from the counting circuitry 31 (step S119). The counting circuitry 31 increments the operation time numbers NAⱼ, NBⱼ and NCⱼ of the operations every time a change of the current I caused by occurrence of an operation is detected before the measurement time Tⱼ elapses (step S117).

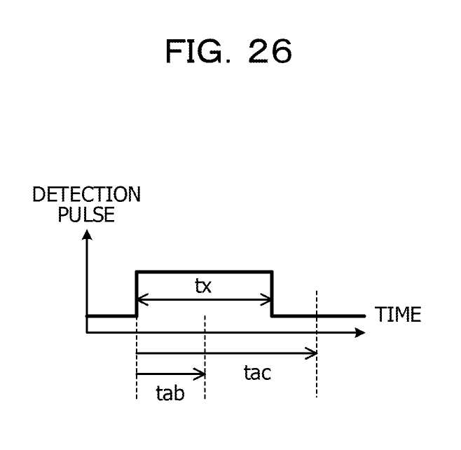

FIG. 26 is a view depicting an example of decision as t_{A}. In order to decide the three operation states at step S119, two time references (tab, tac) for deciding the length of the current change detection time period tx (for example, a length of the current change detection signal in the form of a pulse outputted from the current change detection circuitry 21) are provided as depicted in FIG. 26. The counting circuitry 31 may discriminate the three operation states from each other by comparing tx with tab and tac in magnitude. For example, in the case where tx is equal to or greater than tac, the counting circuitry 31 increments the operation time number NCⱼ of the re-coupling operation by one. In the case where tx is equal to or greater than tab but smaller than tac, the counting circuitry 31 increments the operation time number NAⱼ of the sensing operation by one. In the case where tx is smaller than tab, the counting circuitry 31 increments the operation time number NBⱼ of the wireless communication operation by one. Although, in this example, three operation states are discriminated from each other, if the number of time references is increased, since three or more operation states may be distinguished, the scalability is high.

Referring to FIG. 25, in the case where the residual energy calculation circuitry 32 decides at step S115 that the measurement time Tⱼ elapses, the residual energy calculation circuitry 32 acquires the current integrated amount Cⱼ measured in the measurement time Tⱼ by the Coulomb counter 13 from the Coulomb counter 13 and saves the current integrated amount Cⱼ into the memory 29 (refer to FIG. 6) (step S121).

The residual energy calculation circuitry 32 decides whether or not j is greater than 2 (step S124), and in the case where j is not greater than 2, the residual energy calculation circuitry 32 increments j (step S127) and performs the process at step S115 again. The process at step S124 is provided to wait that four or more equations are complete. On the other hand, in the case where j is greater than 2 (for example, in the case where j is 3 or more and four or more equations are complete), the residual energy calculation circuitry 32 solves the simultaneous equations of the expression (*11) to calculate C_{A}, C_{B}, C_{C} and I_{B} (step S129).

In the case where the residual energy calculation circuitry 32 fails to solve the simultaneous functions at steps S129 and S130, it continues the measurement until data with which the simultaneous functions may be solved become complete. The indefinite condition at step S130 is that, for example, at least one of the calculated values of C_{A}, C_{B}, C_{C} and I_{B} assumes a value equal to or smaller than 0 or assumes a value that is physically unreasonable or the like.

At step S131, the residual energy calculation circuitry 32 saves C_{A}, C_{B}, C_{C} and I_{B} calculated at step S129 into the memory 29. At step S133, the residual energy calculation circuitry 32 turns off the switch 23 after C_{A}, C_{B}, C_{C} and I_{B} are saved in the memory 29. In response to the turning off of the switch 23, the operation of the Coulomb counter 13 stops.

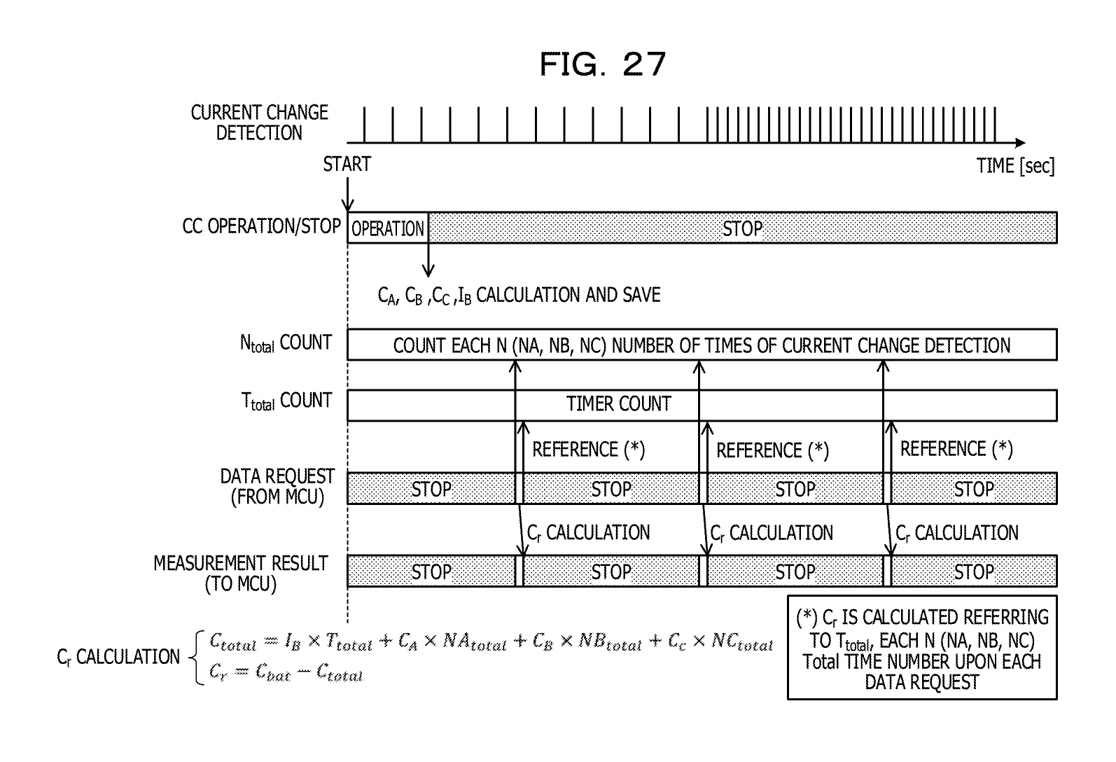

FIG. 27 is a time chart depicting a third operation example of the battery's residual energy measurement circuit. After C_{A}, C_{B}, C_{C} and I_{B} are calculated and saved once in accordance with FIG. 25 upon starting of operation of the sensor node, the residual energy calculation circuitry 32 stops the Coulomb counter 13. The counting circuitry 31 continues to normally count the total operation time numbers (NAₜₒₜₐₗ, NBₜₒₜₐₗ and NCₜₒₜₐₗ) and the timer 26 continues to normally count the total operating time Tₜₒₜₐₗ. At a timing at which a residual energy data request from the MCU 17 is received, the residual energy calculation circuitry 32 calculates the residual energy Cᵣ of the battery 12 in accordance with the expressions (21) and (22) using NAₜₒₜₐₗ, NBₜₒₜₐₗ, NCₜₒₜₐₗ and Tₜₒₜₐₗ at the timing and transmits a residual energy Cᵣ that is a result of the calculation to the MCU 17.

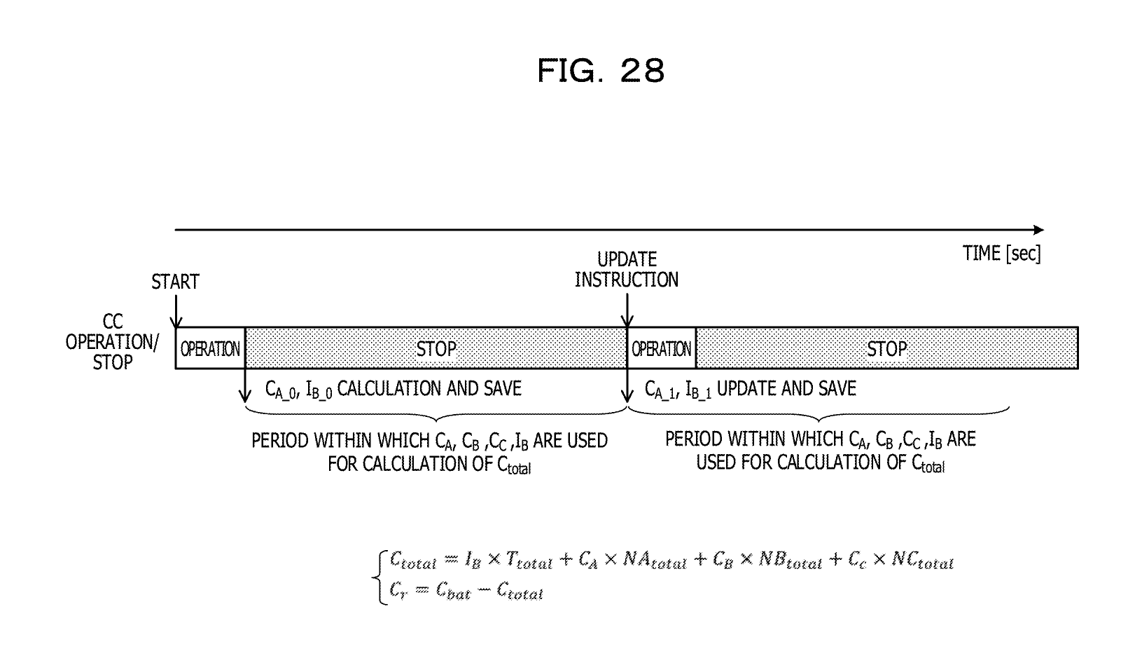

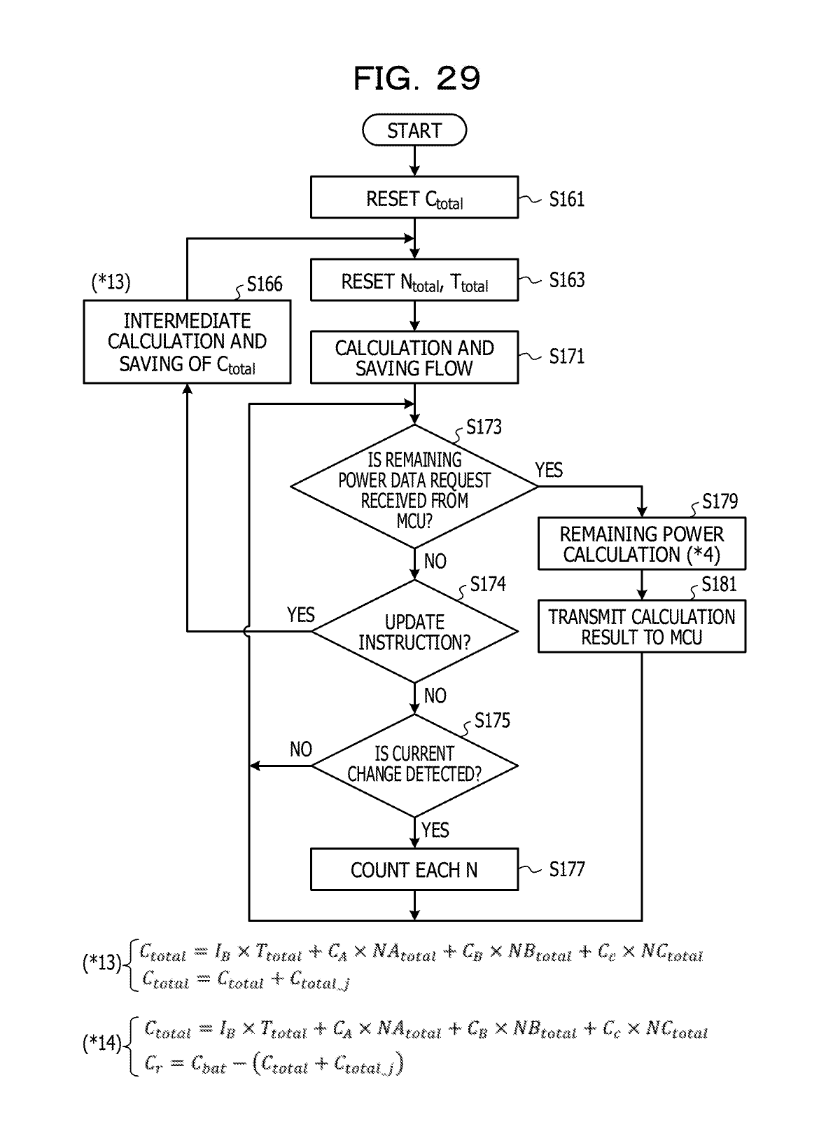

In the third operation example depicted in FIGS. 25 and 27, C_{A}, C_{B}, C_{C} and I_{B} are calculated and saved once upon starting of operation of the sensor node, and calculation of the battery's residual energy continues using C_{A}, C_{B}, C_{C} and I_{B} saved in this manner. However, actually there are many cases in which C_{A}, C_{B}, C_{C} and I_{B} vary depending upon a change of the environment. Therefore, an example is conceivable in which, in response to occurrence of a given event, the residual energy calculation circuitry 32 re-calculates and uses C_{A}, C_{B}, C_{C} and I_{B} for updating. The given event occurs, for example, periodically or in response to a temperature change. In FIGS. 28 and 29, an example in which C_{A}, C_{B}, C_{C} and I_{B} are re-calculated and used for updating (fourth operation example) is depicted.

In the fourth operation example of FIGS. 28 and 29, operation of the Coulomb counter 13 in a stopping state is re-started at a point of time at which an updating instruction is received, and the C_{A}, C_{B}, C_{C} and I_{B} calculation and saving flow of FIG. 25 is rendered operative to update C_{A}, C_{B}, C_{C} and I_{B}. After the updating, the updated values are used to calculate the battery's residual energy. The fourth operation example is different from the third operation example in that the C_{A}, C_{B}, C_{C} and I_{B} calculating and saving flow of FIG. 25 is rendered operative when an updating instruction is received in addition to upon starting of operation of the sensor node.

At step S161, the residual energy calculation circuitry 32 resets the total current integrated amount Cₜₒₜₐₗ. At step S163, the residual energy calculation circuitry 32 resets the total operation time numbers NAₜₒₜₐₗ, NBₜₒₜₐₗ and NCₜₒₜₐₗ and the total operating time Tₜₒₜₐₗ.

At step S171, the residual energy calculation circuitry 32 executes the C_{A}, C_{B}, C_{C} and I_{B} calculating and saving flow of FIG. 25.

At step S173, the residual energy calculation circuitry 32 decides whether or not a residual energy data request is received from the MCU 17. If a residual energy data request is not received, the residual energy calculation circuitry 32 decides whether or not an updating instruction is received from the MCU 17 (step S174). In the case where an updating instruction is not received, the residual energy calculation circuitry 32 acquires the total operation time numbers NAₜₒₜₐₗ, NBₜₒₜₐₗ and NCₜₒₜₐₗ from the counting circuitry 31 (step S177). The counting circuitry 31 increments the total operation time number of the operation that has varied the current I from among the total operation time numbers NAₜₒₜₐₗ, NBₜₒₜₐₗ and NCₜₒₜₐₗ every time a change of the current I caused by occurrence of each operation is detected before an updating instruction is received (step S175).

On the other hand, in the case where the residual energy calculation circuitry 32 decides at step S174 that an updating instruction is received, the residual energy calculation circuitry 32 calculates intermediate data of the total current integrated amount Cₜₒₜₐₗ in accordance with the expression (*13) and temporarily saves the calculated intermediate data into the memory 29 (step S166).

For example, in the case where an i+1th updating instruction is received at step S174, the residual energy calculation circuitry 32 calculates the total current integrated value Cₜₒₜₐₗ using data (C_{A}_{_}ᵢ, C_{B}_{_}ᵢ, C_{C}_{_}ᵢ and I_{B}_{_{—hd i}}) of the ith charge and base current before it calculates C_{A}_{_}ᵢ₊₁, C_{B}_{_}ᵢ₊₁, C_{C}_{_}ᵢ₊₁ and I_{B}_{_}ᵢ₊₁. Then, the residual energy calculation circuitry 32 sums calculated Cₜₒₜₐₗ_{_}ᵢ to Cₜₒₜₐₗ till the i−1th total current integrated amount. Thereafter, the residual energy calculation circuitry 32 resets Tₜₒₜₐₗ, NAₜₒₜₐₗ, NBₜₒₜₐₗ and NCₜₒₜₐₗ at step S163 and enters the i+1th calculation flow. The variable i represents an integer equal to or greater than 0.

On the other hand, in the case where the residual energy calculation circuitry 32 decides at step S173 that a residual energy data request is received, it calculates Cₜₒₜₐₗ_{_}ᵢ using C_{A}_{_}ᵢ, C_{B}_{_}ᵢ, C_{C}_{_}ᵢ, Tₜₒₜₐₗ, NAₜₒₜₐₗ, NBₜₒₜₐₗ and NCₜₒₜₐₗ at the point of time in accordance with the expression (*14). The residual energy calculation circuitry 32 sums calculated Cₜₒₜₐₗ_{_}ᵢ to Cₜₒₜₐₗ till the point of time to calculate the residual energy Cr in accordance with the expression (*14) (step S179). At step S181, the residual energy calculation circuitry 32 transmits the residual energy Cᵣ of a result of the calculation to the MCU 17.

It is to be noted that, although only an operation time period and a stopping time period of the Coulomb counter are depicted in FIG. 28, in the entire time chart, portions other than the operation/stopping of the Coulomb counter are similar to those in FIG. 27.

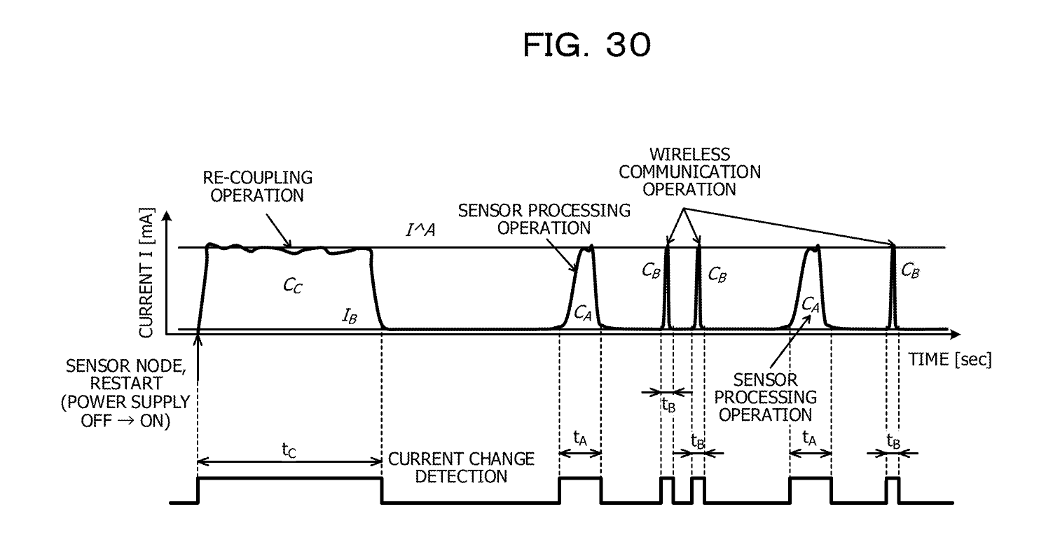

Incidentally, FIGS. 23 to 29 are directed to an example in which consumption charge amounts (C_{A}, C_{B} and C_{C}) in a plurality of operation states are defined and, after each operation state is discriminated, each operation time number is counted (NA, NB and NC) to calculate a battery's residual energy. FIG. 30 is a view depicting a third particular example of a relation between a current waveform and a current change detection signal. Even if the operation currents in the operations are uniformly approximated to an unknown I_{A} as in FIG. 30 without performing discrimination of the operation state, there is a case in which the accuracy in residual energy calculation is not damaged very much.

In this case, not the number of times by which each operation that changes the current I occurs is measured but the period of time within which an operation that changes the current I occurs may be measured to perform residual energy calculation. The period of time within which an operation that changes the current I may be measured by the counting circuitry 31, for example, based on the length of the current change detection signal in the form of a pulse outputted from the current change detection circuitry 21. If the operation currents in the operations are approximated uniformly by the unknown I_{A}, the consumption charge amounts C_{A}, C_{B} and C_{C} per one time operation of the re-coupling operation, sensor processing operation and wireless communication operation, respectively, may be approximated like C_{A}=I_{A}×t_{A}, C_{B}=I_{A}×t_{B} and C_{C}=I_{A}×t_{C}. If the counting circuitry 31 counts the total time period tₜₒₜₐₗ, in which a current change is detected, as an operation time period, Cₜₒₜₐₗ and Cᵣ may be represented as

Cₜₒₜₐₗ=I_{B}×Tₜₒₜₐₗ+I_{A}×tₜₒₜₐₗ (31)

Cᵣ=C_{bat}−Cₜₒₜₐₗ (32)

Tₜₒₜₐₗ represents the total operation time of the sensor node (for example, elapsed time period after the base current I_{B} begins to flow). tₜₒₜₐₗ represents the total operating time of all operations that change the current I (total of time periods within which the operations occur in the total operation time Tₜₒₜₐₗ). By making the current consumption values in the operations are made same I_{A}, the unknowns are narrowed down to the 2 unknowns I_{A} and I_{B} irrespective of whether the number of types of operation states is great or small, and therefore, it is possible to simplify the calculation algorithm. Further, by setting the current consumption values in the operations to the same I_{A}, the discrimination of an operation state becomes unnecessary. Therefore, even if the controller 28 does not acquire operation information representative of occurrence of a re-coupling operation or the like from the MCU 17, it may measure the current integrated amount caused by an operation that changes the current I and may utilize the measurement value for calculation of the battery's residual energy.

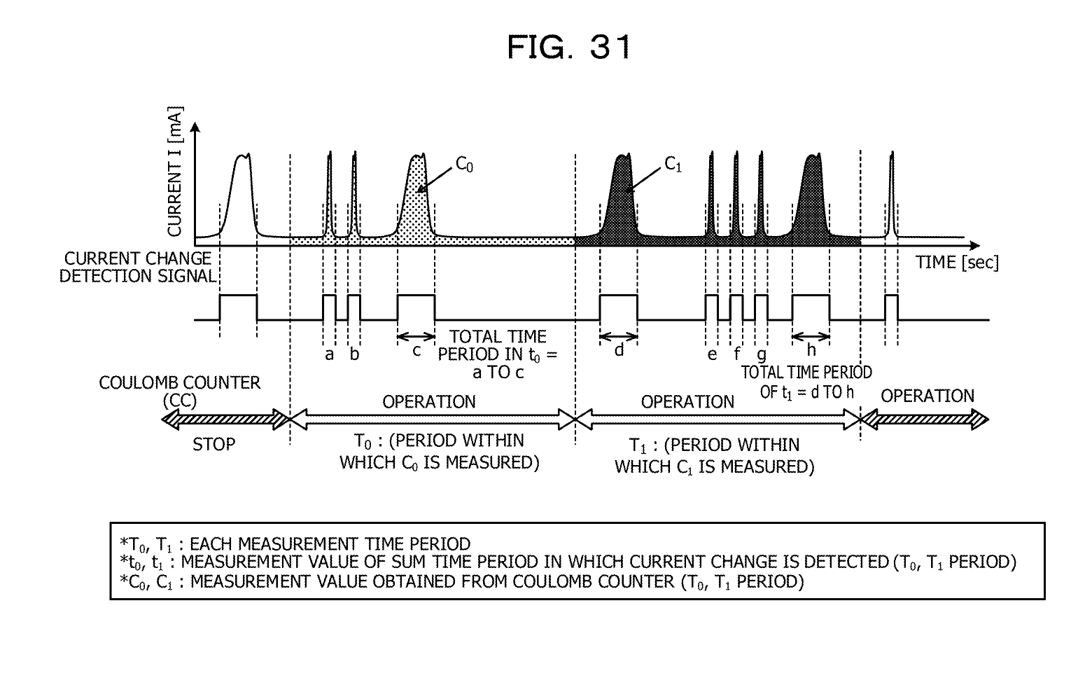

FIG. 31 is a view depicting a third particular example of the calculation algorithm of the battery's residual energy. Basically, since the way of thinking in this case is similar to that described hereinabove with reference to FIGS. 10 and 24 and the number of unknowns is two including I_{A} and I_{B}, the residual energy calculation circuitry 32 acquires the measurement values of the current integrated amount by the Coulomb counter 13 divisionally at least twice during operation of the Coulomb counter 13 (C₀ and C₁) as depicted in FIG. 31. The residual energy calculation circuitry 32 acquires measurement time periods T₀ and T₁ used for C₀ and C₁, respectively, from the timer 26. The residual energy calculation circuitry 32 acquires from the counting circuitry 31 the measurement values (t₀ and t₁) of the total detection time period of a current change within the measurement time periods T₀ and T₁, respectively.

In each of the measurement time periods, the following two expressions are satisfied:

I_{B}×T₀+I_{A}×t₀=C₀ (33)

I_{B}×T₁+I_{A}×t₁=C₁ (34)

The expression (33) signifies that the measured current integrated amount C₀ depends upon the sum of the current integrated amount I_{B}×T₀ and the current integrated amount I_{A}×t₀. This similarly applies also to the expression (34).

Since Cⱼ, Tⱼ and tⱼ are obtained from a result of measurement as described hereinabove (j=0, 1), the residual energy calculation circuitry 32 may calculate the unknowns I_{A} and I_{B} by solving binary simultaneous linear equations according to the expressions (33) and (34).

After I_{A} and I_{B} are calculated, the residual energy calculation circuitry 32 may calculate the residual energy Cᵣ of the battery 12 in accordance with the relational expressions

Cₜₒₜₐₗ=I_{B}×Tₜₒₜₐₗ+I_{A}×tₜₒₜₐₗ (31)

Cᵣ=C_{bat}−Cₜₒₜₐₗ (32)

After I_{A} and I_{B} are calculated, since the current integrated amounts measured by the Coulomb counter 13 are not used for a calculation process of the battery's residual energy by the expressions (31) and (32), the Coulomb counter 13 may be stopped.

Even after the Coulomb counter 13 stops, by causing the timer 26 and the current change detection circuitry 21 to normally operate, the residual energy calculation circuitry 32 may continuously calculate the residual energy Cᵣ of the battery 12 in accordance with the expressions (31) and (32). For example, even if the execute interval of any operation such as a sensing operation is changed after the Coulomb counter 13 stops, since the sensing operation time periods of all operations may be counted accurately by the counting circuitry 31, the calculation accuracy of the battery's residual energy may be maintained high.

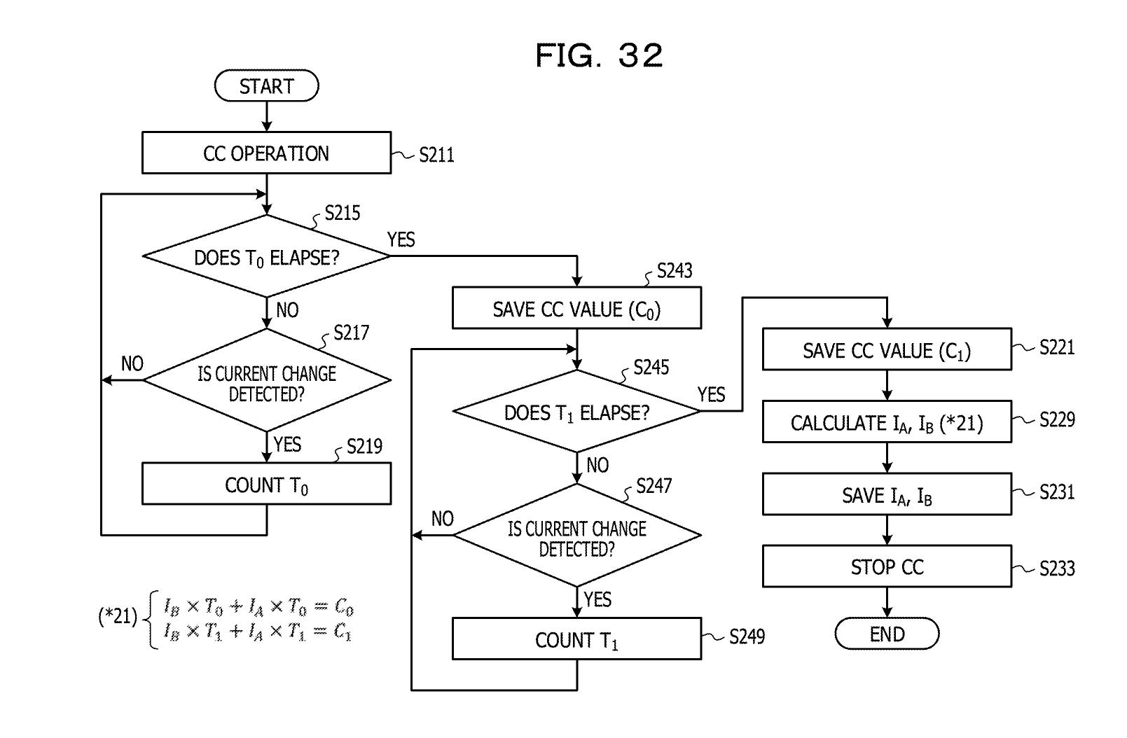

FIG. 32 is a flow chart depicting an example of a process for calculating and saving I_{A} and I_{B}. The way of thinking here is basically similar to that described with reference to FIGS. 11 and 25. Since the number of unknowns is reduced to two including I_{A} and I_{B}, the calculation algorithm may be simplified in comparison with that of FIG. 25.

If the energy-on reset is cancelled by energy supply from the battery 12, the residual energy calculation circuitry 32 turns on the switch 23 (refer to FIG. 6) at step S211. The switch 23 is inserted in series in the path along which energy supply current flowing to the Coulomb counter 13 passes. In response to the turning on of the switch 23, operation of the Coulomb counter 13 is started.

At step S215, the residual energy calculation circuitry 32 decides whether or not the measurement period T₀ elapses. In the case where the measurement period T₀ does not elapse, the residual energy calculation circuitry 32 acquires the period t₀ within which an operation that changes the current I occurs from the counting circuitry 31 (step S219). The counting circuitry 31 counts the period t₀ within which an operation that changes the current I occurs every time a change of the current I caused by occurrence of each operation is detected before the measurement period T₀ elapses (step S217).

In the case where the residual energy calculation circuitry 32 decides at step S215 that the measurement period T₀ elapses, it acquires the current integrated amount C₀ measured in the measurement period T₀ by the Coulomb counter 13 from the Coulomb counter 13 and saves the current integrated amount C₀ into the memory 29 (refer to FIG. 6) (step S243).

At step S245, the residual energy calculation circuitry 32 decides whether or not the measurement time period T₁ elapses. In the case where the measurement time period T₁ does not elapse, the residual energy calculation circuitry 32 acquires the time period t₁ within which an operation that changes the current I occurs from the counting circuitry 31 (step S249). The counting circuitry 31 counts the period t₁ within which an operation that changes the current I occurs every time a change of the current I caused by occurrence of each operation is detected before the measurement period T₁ elapses (step S247).

In the case where the residual energy calculation circuitry 32 decides at step S245 that the measurement time period T₁ elapses, it acquires the current integrated amount C₁ measured in the measurement time period T₁ by the Coulomb counter 13 from the Coulomb counter 13 and saves the current integrated amount C₁ into the memory 29 (refer to FIG. 6) (step S221).

At step S229, the residual energy calculation circuitry 32 calculates I_{A} and I_{B} by solving the simultaneous equations of the expression (*21).

At step S231, the residual energy calculation circuitry 32 saves I_{A} and I_{B} calculated at step S229 into the memory 29. At step S233, after the residual energy calculation circuitry 32 saves I_{A} and I_{B} into the memory 29, it turns off the switch 23. In response to the turning off of the switch 23, the operation of the Coulomb counter 13 stops.

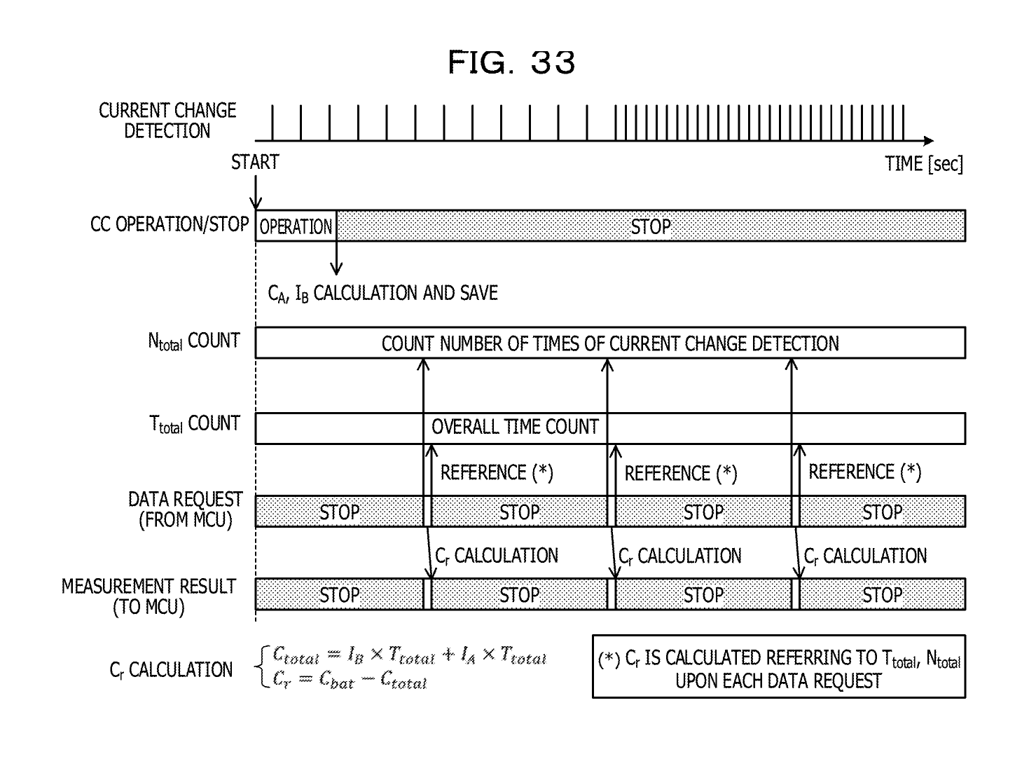

FIG. 33 is a time chart depicting a fifth operation example of the battery's residual energy measurement circuit. The residual energy calculation circuitry 32 stops the Coulomb counter 13 after I_{A} and I_{B} are calculated and saved in accordance with FIG. 32 upon starting of operation of the sensor node. The counting circuitry 31 continues to normally count the total operating time tₜₒₜₐₗ of all operations that change the current I, and the timer 26 continues to normally count the total operating time Tₜₒₜₐₗ. At a timing at which a residual energy data request from the MCU 17 is received, the residual energy calculation circuitry 32 calculates the residual energy Cᵣ of the battery 12 in accordance with the expressions (31) and (32) using tₜₒₜₐₗ and Tₜₒₜₐₗ at the timing and transmits the residual energy Cᵣ that is a result of the calculation to the MCU.

Accordingly, with the embodiments described above, improvement of the calculation accuracy of a battery's residual energy and reduction of current consumption by stopping of the Coulomb counter 13 may be implemented. For example, while, in a sensor node in which the Coulomb counter normally operates, the average current consumption of the sensor processing circuitry is approximately 200 μA, a Coulomb counter that operates normally consumes as high as approximately 80 μA, and therefore, the total current consumption is approximately 280 μA. Accordingly, with the embodiments, while the measurement accuracy of the battery's residual energy is maintained, the current consumption of the Coulomb counter may be reduced to approximately 6 μA. For example, the current consumption of the sensor node may be reduced by approximately 36% from 280 to 206 μA.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A battery's residual energy measurement circuit comprising:
integrated amount measurement circuitry that measures quantity of an integrated amount of current flowing in a battery;
time number measurement circuitry that measures number of times by which a sensing operation that changes the current flowing;
time measurement circuitry that measures time; and
residual energy calculation circuitry that calculates residual energy of the battery using the integrated amount measured within a measurement period by the integrated amount measurement circuitry, the number of times measured within the measurement period by the time number measurement circuitry and the measurement period measured by the time measurement circuitry.

2. The battery's residual energy measurement circuit according to claim 1, wherein
the residual energy calculation circuitry calculates the residual energy of the battery further using base current that normally flows out from the battery and charge discharged from the battery per one time occurrence of the sensing operation.

3. The battery's residual energy measurement circuit according to claim 2, wherein
the residual energy calculation circuitry calculates the residual energy of the battery by subtracting, from a capacity of the battery, a sum of a product of the base current and an elapsed period after the base current begins to flow and a product of the charge and a total number of times by which the sensing operation occurs within the elapsed period.

4. The battery's residual energy measurement circuit according to claim 2, wherein
the residual energy calculation circuitry calculates the base current and the charge using the integrated amount measured within each measurement period by the integrated amount measurement circuitry, the number of times of measurement within each measurement period by the time number measurement circuitry and the measurement periods measured by the time measurement circuitry.

5. The battery's residual energy measurement circuit according to claim 4, wherein
the integrated amount measurement circuitry stops the measurement of the integrated amount after the base current and the charge are calculated.

6. The battery's residual energy measurement circuit according to claim 5, wherein
the integrated amount measurement circuitry re-starts the measurement of the integrated amount when a given event occurs while the measurement of the integrated amount is stopped; and
the residual energy calculation circuitry re-calculates and uses the base current and the charge for updating.

7. The battery's residual energy measurement circuit according to claim 1, further comprising:
current change detection circuitry that detects occurrence of the sensing operation based on increase of the current; wherein
the time number measurement circuitry measures the number of times based on a result of the detection of the current change detection circuitry.

8. The battery's residual energy measurement circuit according to claim 1, wherein
the time number measurement circuitry measures, in addition to the number of times by which the sensing operation occurs, the number of times by which at least one different operation that changes the current occurs; and
the residual energy calculation circuitry calculates the residual energy of the battery further using the number of times of occurrence of the different operation measured within the measurement period by the time number measurement circuitry.

9. The battery's residual energy measurement circuit according to claim 8, wherein
the residual energy calculation circuitry calculates the residual energy of the battery further using base current that normally flows out from the battery, charge discharged from the battery per one time occurrence of the sensing operation and charge discharged from the battery per one time occurrence of the different operation.

10. The battery's residual energy measurement circuit according to claim 9, wherein
the residual energy calculation circuitry calculates the residual energy of the battery by subtracting, from a capacity of the battery, a sum of a product of the base current and an elapsed period after the base current begins to flow, a product of charge discharged from the battery per one time occurrence of the sensing operation and a total number of times by which the sensing operation occurs within the elapsed period, and a product of charge discharged from the battery per one time occurrence of the different operation and a total number of times by which the different operation occurs within the elapsed period.

11. The battery's residual energy measurement circuit according to claim 9, wherein
the residual energy calculation circuitry calculates the base current, charge discharged from the battery per one time occurrence of the sensing operation and charge discharged from the battery per one time occurrence of the different operation using the integrated amount measured within each measurement period by the integrated amount measurement circuitry, the number of times of occurrence of the sensing operation measured within each measurement period by the time number measurement circuitry, the number of times of occurrence of the different operation measured within each measurement period by the time number measurement circuitry and the measurement periods measured by the time measurement circuitry.

12. The battery's residual energy measurement circuit according to claim 11, wherein
the integrated amount measurement circuitry stops the measurement of the integrated amount after the base current, charge discharged from the battery per one time occurrence of the sensing operation and charge discharged from the battery per one time occurrence of the different operation are calculated.

13. The battery's residual energy measurement circuit according to claim 12, wherein
the integrated amount measurement circuitry re-starts the measurement of the integrated amount in response to occurrence of a given event during stopping of the measurement of the integrated amount; and
the residual energy calculation circuitry re-calculates and uses the base current, charge discharged from the battery per one time occurrence of the sensing operation and charge discharged from the battery per one time occurrence of the different operation for updating.

14. The battery's residual energy measurement circuit according to claim 8, further comprising:
current change detection circuitry that detects occurrence of the sensing operation and the different operation based on increase of the current; wherein
the time number measurement circuitry measures the number of times of occurrence of the sensing operation and the different operation based on a result of the detection by the current change detection circuitry.

15. The battery's residual energy measurement circuit according to claim 8, wherein
the sensing operation and the different operation are discriminated from each other based on a difference in length of a period of time within which the operation that changes the current occurs.

16. The battery's residual energy measurement circuit according to claim 6, wherein
the given event occurs periodically or in response to a temperature variation.

17. A sensor node comprising:
a battery;
a sensor;
sensor processing circuitry that performs a sensing operation of transmitting data detected by the sensor to outside of the sensor node using energy from the battery;
integrated amount measurement circuitry that measures an integrated amount of current flowing to the battery;
time number measurement circuitry that measures the number of times by which the sensing operation occurs;
time measurement circuitry that measures time; and
residual energy calculation circuitry that calculates residual energy of the battery using the integrated amount measured within a measurement period by the integrated amount measurement circuitry, the number of times measured within the measurement period by the time number measurement circuitry and the measurement period measured by the time measurement circuitry.

18. A battery's residual energy measurement circuit comprising:
integrated amount measurement circuitry that measures an integrated amount of current flowing to a battery;
counting circuitry that measures an occurrence time period within which an operation that changes the current occurs;
time measurement circuitry that measures time; and
residual energy calculation circuitry that calculates residual energy of the battery using the integrated amount measured within a measurement period by the integrated amount measurement circuitry, the occurrence time period measured within the measurement period by the counting circuitry and the measurement period measured by the time measurement circuitry.

19. The battery's residual energy measurement circuit according to claim 18, wherein
the residual energy calculation circuitry calculates the residual energy of the battery further using base current that normally flows out from the battery and operating current of the operation.
